(19) United States
(12) Patent Application Publication
(10) Pub. No.: US 2026/0190694 A1
(43) Pub. Date: Jul. 2, 2026

(54) DISPLAY PANEL AND ELECTRONIC APPARATUS INCLUDING THE DISPLAY PANEL

(71) Applicant: Samsung Display Co., LTD., Yongin-si (KR)

(72) Inventors: Sangwoo Kim, Yongin-si (KR); Hosik Shin, Yongin-si (KR); Hyungsoo Yoon, Samsung-ro (KR); Hyejin Joo, Yongin-si (KR); Myunghee Han, Yongin-si (KR); Jongho Hong, Yongin-si (KR)

(21) Appl. No.: 19/320,015

(22) Filed: Sep. 5, 2025

(30) Foreign Application Priority Data
Dec. 31, 2024 (KR) 10-2024-0202696

(51) Int. Cl. H10K 59/131; H10K 59/121; H10K 102/00

(52) U.S. Cl. CPC H10K 59/131; H10K 59/1213; H10K 2102/311

(57) ABSTRACT

An embodiment of the present invention discloses a display panel including a display area and a non-display area outside the display area and an electronic apparatus including the same. The display panel includes island portions apart from each other in a first direction and a second direction perpendicular to the first direction in the display area; and bridge portions respectively connecting two island portions adjacent to each other among the island portions, the bridge portions being apart from each other by openings, wherein each of the island portions includes a first side crossing a first imaginary line passing through centers of the island portions and extending in the first direction, and wherein an angle formed by the first side and the first imaginary line is greater than 45° and less than 90°.

### TECHNICAL FIELD

Embodiments of the present invention relate to a display panel, for example, a flexible display panel, and an electronic apparatus including the same.

### PRIOR ART

With the development of display panels that visually display electrical signals, various display panels having excellent characteristics such as thinness, light weight, low power consumption, and the like have been introduced. As an example, flexible display panels that are foldable or rollable in a roll shape have been introduced. Recently, research and development into display panels of various structures, such as stretchable display panels that may be changed into various shapes, are actively in progress.

### DISCLOSURE OF THE INVENTION

### Technical Goal of the Invention

Embodiments of the present invention provide a display panel, for example, a flexible display panel, and an electronic apparatus including the same. However, such an objective is an example, and the scope of the present invention is not limited thereto.

### Means for Achieving Technical Goal

One aspect of the present invention discloses a display panel including a display area and a non-display area outside the display area, the display panel including: island portions apart from each other in a first direction and a second direction in the display area, wherein the second direction is perpendicular to the first direction; and bridge portions respectively connecting two island portions adjacent to each other among the island portions, the bridge portions being apart from each other by openings, wherein each of the island portions includes a first side crossing a first imaginary line passing through centers of the island portions and extending in the first direction, and wherein an angle formed by the first side and the first imaginary line is greater than 45° and less than 90°.

In an embodiment, one of the bridge portions may be disposed within a first imaginary quadrilateral having centers of four island portions adjacent to the bridge portion as vertexes.

In an embodiment, the first imaginary quadrilateral may be a square.

In an embodiment, the island portions may include first island portions and second island portions alternately disposed in the first direction and the second direction, and each of the bridge portions may connect a first island portion and a second island portion adjacent to each other among the island portions.

In an embodiment, in the first island portions and the second island portions, angles formed by the first side and the first imaginary line may be equal to each other. In an embodiment, one end of each of the bridge portions may be connected to a corner of one side of the first island portion, and another end of each of the bridge portions may be connected to a portion apart from a corner of one side of the second island portion.

In an embodiment, one side of the first island portion and one side of the second island portion connected to one of the bridge portions may be disposed in directions crossing each other.

In an embodiment, the bridge portions may each have a curved shape.

In an embodiment, one end of each of the bridge portions may be connected to a portion apart from a corner of one side of the first island portion, and another end of each of the bridge portions may be connected to a portion apart from a corner of one side of the second island portion.

In an embodiment, one end of each of the bridge portions may be connected to a corner of one side of the first island portion, and another end of each of the bridge portions may be connected to a corner of one side of the second island portion.

In an embodiment, the island portions may include a first island portion and a second island portion respectively disposed at a first vertex and a second vertex facing each other among vertexes of the first imaginary quadrilateral, and a third island portion and a fourth island portion respectively disposed at a third vertex and a fourth vertex facing each other, wherein, within the first imaginary quadrilateral, one side of the first island portion and one side of the second island portion may face each other, and one side of the third island portion and one side of the fourth island portion may face each other, wherein two sides of the first island portion and the second island portion facing each other, and two sides of the third island portion and the fourth island portion facing each other, may overlap four sides of a second imaginary quadrilateral, respectively, and wherein the bridge portions may be disposed within the second imaginary quadrilateral.

In an embodiment, the second imaginary quadrilateral may be a square.

In an embodiment, each of the island portions may include a transistor and a light-emitting element electrically connected to the transistor, and each of the bridge portions may include wirings electrically connected to a transistor of at least one island portion among the island portions.

In an embodiment, the display panel may be stretchable, and when the display panel is stretched, the island portions may rotate clockwise or counterclockwise around an axis passing through the center of each of the island portions.

Another aspect of the present invention discloses an electronic apparatus including: a display panel providing images; and a housing accommodating the display panel, wherein the display panel includes: island portions disposed in a display area and apart from each other in a first direction and a second direction perpendicular to the first direction; and bridge portions connecting two island portions adjacent to each other among the island portions, the bridge portions being apart from each other by openings, wherein the island portions have a quadrangular shape, wherein each of the island portions includes a first side crossing an imaginary straight line extending in the first direction, the imaginary straight line passing through centers of the island portions, and wherein an inferior angle of angles formed by the first side and the imaginary straight line is greater than 45° and less than 90°.

In an embodiment, the electronic apparatus may further include a strain sensor measuring a physical quantity according to stretching of the display panel.

In an embodiment, one of the bridge portions may be disposed within a first imaginary quadrilateral having centers of four island portions adjacent to the bridge portion as vertexes.

In an embodiment, the island portions may include first island portions and second island portions alternately disposed in the first direction and the second direction, and each of the bridge portions may connect a first island portion and a second island portion adjacent to each other among the island portions.

In an embodiment, one end of each of the bridge portions may be connected to a corner of one side of the first island portion, and another end of each of the bridge portions may be connected to a portion apart from a corner of one side of the second island portion.

In an embodiment, one side of the first island portion and one side of the second island portion connected to one of the bridge portions may be disposed in directions crossing each other.

### Effect of the Invention

According to an embodiment of the present invention, a display panel which is stretchable in various directions, and an electronic apparatus including the same may be provided. In the display panel, damage due to stress concentration may be reduced and/or the area of an opening may be reduced, and thus, a resolution may be improved. This effect is an example, and the scope of the present invention is not limited by the effect.

### BRIEF DESCRIPTION OF THE DRAWINGS

FIG. 1 is a schematic perspective view of a display panel according to an embodiment.

FIGS. 2A and 2B are perspective views of the display panel of FIG. 1 stretched in a first direction.

FIG. 2C is a perspective view of the display panel of FIG. 1 stretched in a second direction.

FIG. 2D is a perspective view of the display panel of FIG. 1 stretched in the first direction and the second direction.

FIG. 2E is a perspective view of the display panel of FIG. 1 stretched in a third direction.

FIG. 3 is a plan view of a display panel according to an embodiment.

FIG. 4A is an enlarged plan view of a portion of a display panel, showing a region IV of FIG. 3 according to an embodiment.

FIG. 4B is an enlarged plan view of a portion of a display panel, showing a region IV of FIG. 3 according to an embodiment.

FIG. 5 is a schematic cross-sectional view of an island portion and a bridge portion disposed in a display area of a display panel according to an embodiment.

FIGS. 6A to 6C are equivalent circuit diagrams of a light-emitting element and a pixel driving circuit portion electrically connected thereto of a display panel according to an embodiment.

FIGS. 7A and 7B are schematic cross-sectional views of a light-emitting element of a display panel according to an embodiment.

FIGS. 8A and 8B are plan views of island portions and bridge portions disposed in a display area of a display panel of FIG. 4A.

FIG. 9A is a plan arrangement view of a first island portion and bridge portions connected thereto of FIGS. 8A and 8B.

FIG. 9B is a plan arrangement view of a second island portion and bridge portions connected thereto of FIGS. 8A and 8B.

FIGS. 10A to 10D are plan arrangement views of arrangement of pixels of a display panel according to an embodiment.

FIGS. 11A to 11E are plan views of island portions and bridge portions disposed in a display area of a display panel according to an embodiment.

FIG. 12A is a schematic perspective view of an electronic apparatus including a display panel according to an embodiment.

FIG. 12B is a schematic block diagram of an electronic apparatus including a display panel according to an embodiment.

FIGS. 13A to 131 are schematic perspective views of an electronic apparatus including a display panel according to an embodiment.

### DESCRIPTION OF EMBODIMENT

As the present invention allows for various changes and numerous embodiments, certain embodiments will be illustrated in the drawings and described in the detailed description. Effects and features of the present invention, and methods for achieving them will be clarified with reference to embodiments described below with reference to the drawings. However, the present invention is not limited to embodiments described below and may be implemented in various forms.

Hereinafter, embodiments of the present invention will be described with reference to the accompanying drawings, wherein like or corresponding elements are given like reference characters when describing with reference to the drawings, and a repeated description thereof is omitted.

In embodiments below, such terms as first and second are not used in a limited meaning and are used for the purpose of distinguishing one element from another.

In embodiments below, the singular expressions include the plural expressions unless the context clearly indicates otherwise.

In embodiments below, the terms “comprise,” or “include” as used herein specify the presence of stated features or elements but do not preclude the addition of one or more other features or elements.

In embodiments below, when a layer, region, or element is referred to as being on another portion, it may include not only a case where the layer, region, or element is directly on the other portion, but also a case where intervening layers, regions, or elements are disposed therebetween.

Sizes of elements in the drawings may be exaggerated or reduced for convenience of explanation. As an example, the size and thickness of each element shown in the drawings are arbitrarily represented for convenience of description, and thus, the present invention is not necessarily limited thereto.

In the case where a certain embodiment may be implemented differently, a specific process order may be performed in the order different from the described order. As an example, two processes successively described may be simultaneously performed substantially and performed in the opposite order of the described order.

In the present specification, “A and/or B” means A or B, or A and B. In addition, “at least one of A and B” means A or B, or A and B.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the present specification, when a layer, region, or element is referred to as being electrically connected, it represents a case where the layer, region, or element is directly electrically connected and/or a case where the layer, region, or element may be indirectly electrically connected with another layer, region, or element disposed therebetween.

An x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

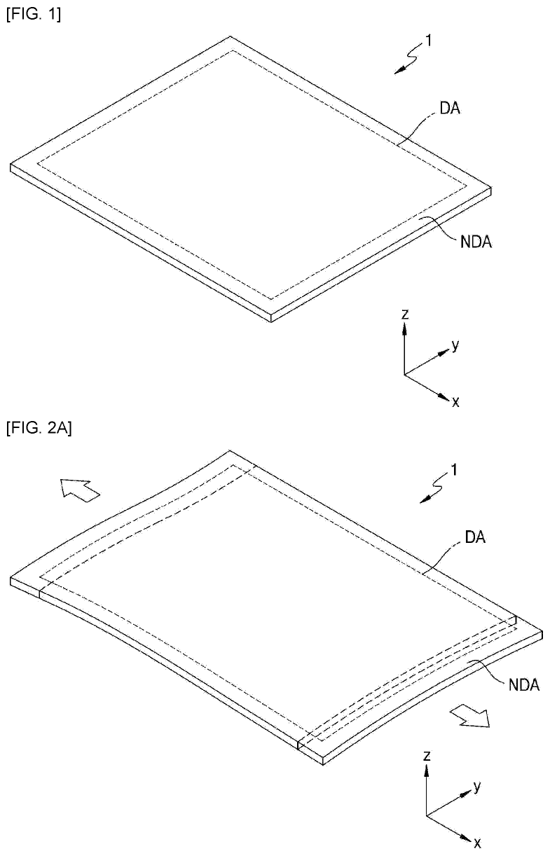

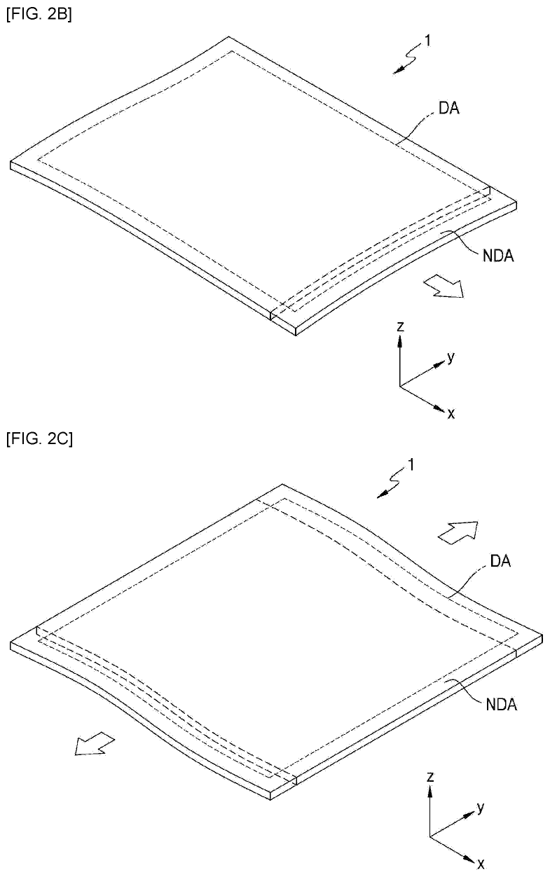

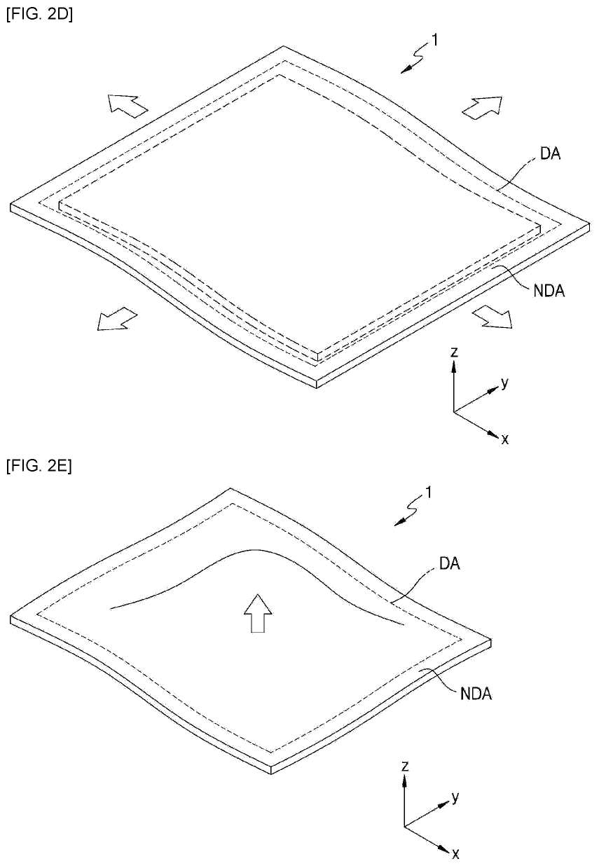

FIG. 1 is a schematic perspective view of a display panel 1 according to an embodiment. FIGS. 2A and 2B are perspective views of the display panel 1 of FIG. 1 stretched in a first direction. FIG. 2C is a perspective view of the display panel 1 of FIG. 1 stretched in a second direction. FIG. 2D is a perspective view of the display panel 1 of FIG. 1 stretched in the first direction and the second direction. FIG. 2E is a perspective view of the display panel 1 of FIG. 1 stretched in a third direction.

Referring to FIG. 1, the display panel 1 may include a display area DA and a non-display area NDA. The display area DA may include a plurality of pixels. The display panel 1 may be configured to display images by using light emitted from the plurality of pixels. The non-display area NDA may be disposed outside the display area DA. The non-display area NDA is a region in which the pixels are not disposed and may surround the display area DA entirely.

The display panel 1 may be stretched or shrunk in various directions. The display panel 1 may be stretched in the first direction (e.g., an x direction and/or −x direction) by an external force exerted by an external object or a user. In an embodiment, as shown in FIGS. 2A and 2B, the display area DA and/or the non-display area NDA of the display panel 1 may be stretched in the first direction (e.g., the x direction and/or −x direction). As an example, as shown in FIG. 2A, the display area DA and/or the non-display area NDA may be stretched in the x direction and −x direction, or as shown in FIG. 2B, be stretched in the x direction with one side of the display panel 1 fixed.

The display panel 1 may be stretched in the second direction (e.g., a y direction and/or −y direction) by an external force exerted by an external object or a user. In an embodiment, as shown in FIG. 2C, the display area DA and/or the non-display area NDA of the display panel 1 may be stretched in the y direction and −y direction. In another embodiment, the display panel 1 may be stretched in the y direction or −y direction with one side of the display panel 1 fixed.

The display panel 1 may be stretched in a plurality of directions, for example, the first direction (e.g., the x direction and/or −x direction) and the second direction (e.g., the y direction and/or −y direction) by an external force exerted by an external object or a portion of a person's body. As shown in FIG. 2D, the display area DA and/or the non-display area NDA of the display panel 1 may be stretched in the ±x directions and ±y directions.

The display panel 1 may be stretched in a third direction (e.g., a z direction and/or −z direction) by an external force exerted by an external object or a portion of a person's body. In an embodiment, FIG. 2E shows a portion of the display panel 1, for example, a partial region of the display area DA protrudes in the z direction. In another embodiment, a portion of the display panel 1, for example, a partial region of the display area DA may protrude in the −z direction (or be recessed in the z direction).

Although it is shown in FIGS. 2A to 2E that the display panel 1 is stretched in the first direction, the second direction, and/or the third direction, the present invention is not limited thereto. In another embodiment, the display panel 1 may be variously transformed into an irregular shape by, for example, bending or twisting around two or more axes.

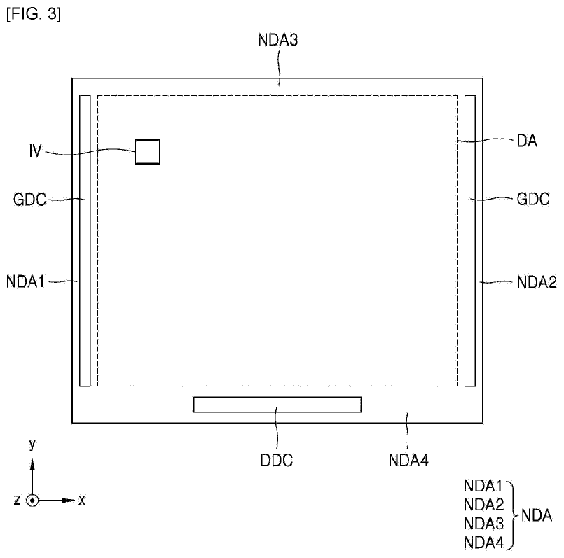

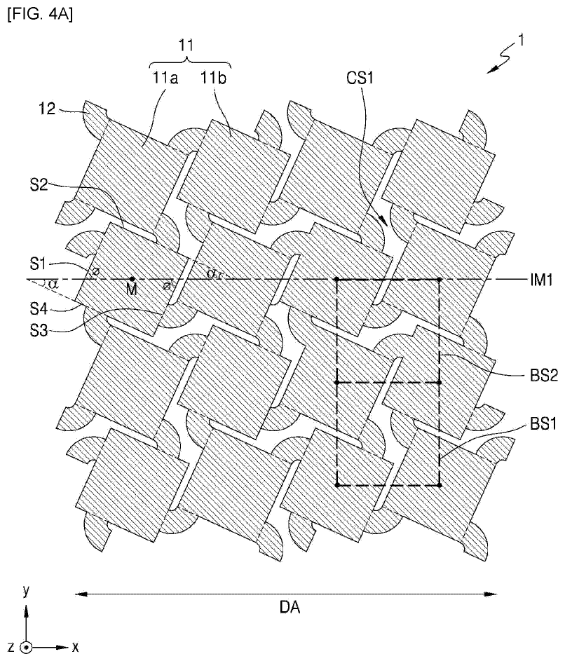

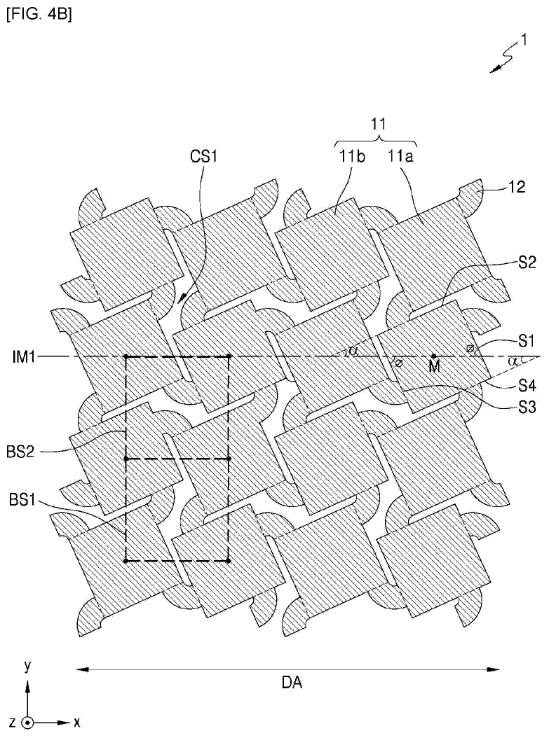

FIG. 3 is a plan view of the display panel 1 according to an embodiment.

Referring to FIG. 3, the plurality of pixels may be arranged in the display area DA of the display panel 1. Each pixel may include sub-pixels emitting light of different colors. A light-emitting element corresponding to each sub-pixel may be disposed in the display area DA. A circuit may be located in the non-display area NDA around the display area DA, wherein the circuit provides electrical signals to light-emitting elements disposed in the display area DA and transistors electrically connected to the light-emitting elements. A gate driving circuit GDC may be disposed in each of a first non-display area NDA1 and a second non-display area NDA2 disposed on two opposite sides with the display area DA therebetween. The gate driving circuit GDC may include drivers for providing electrical signals to a gate electrode of each of transistors electrically connected to the light-emitting elements. Although it is shown in FIG. 3 that the gate driving circuit GDC is disposed in each of the first non-display area NDA1 and the second non-display area NDA2, the present invention is not limited thereto. In another embodiment, the gate driving circuit GDC may be disposed in one of the first non-display area NDA1 and the second non-display area NDA2.

A data driving circuit DDC may be disposed in a third non-display area NDA3 and/or a fourth non-display area NDA4 connecting the first non-display area NDA1 and the second non-display area NDA2 to each other. In an embodiment, it is shown in FIG. 3 that the data driving circuit DDC is disposed in the fourth non-display area NDA4. In another embodiment, the data driving circuit DDC may be disposed in each of the third non-display area NDA3 and the fourth non-display area NDA4.

Although it is shown in FIG. 3 that the data driving circuit DDC is disposed in the fourth non-display area NDA4 of the display panel 1, the present invention is not limited thereto. In another embodiment, the display panel 1 may further include a flexible circuit board (not shown) electrically connected through a terminal section (not shown) disposed in the fourth non-display area NDA4, and the data driving circuit DDC may be disposed on the flexible circuit board.

In another embodiment, an elongation rate of the non-display area NDA may be equal to or less than an elongation rate of the display area DA. In an embodiment, an elongation rate of the non-display area NDA may be different for each region. As an example, the first non-display area NDA1, the second non-display area NDA2, and the third non-display area NDA3 may have substantially the same elongation rate, but an elongation rate of the fourth non-display area NDA4 may be less than an elongation rate of each of the first non-display area NDA1, the second non-display area NDA2, and the third non-display area NDA3. In the present specification, an elongation rate is a numerical value representing a change AL/L in length by which the display panel 1 may be stretched without a physical damage to the display panel 1 when an external force is applied to the display panel 1. Here, AL is the amount of change in length of the display panel 1, and L represents an initial length of the display panel 1.

FIGS. 4A and 4B are enlarged plan views of a portion of the display panel, showing a region IV of FIG. 3 according to an embodiment.

Referring to FIGS. 4A and 4B, the display panel 1 may include island portions 11 and bridge portions 12 connecting adjacent island portions 11, wherein the island portions 11 are apart from each other in the first direction (e.g., the x direction or −x direction) and the second direction (e.g., the y direction or-y direction) in the display area DA. The bridge portions 12 may be apart from each other by a first opening CS1 located between the bridge portions 12.

The island portions 11 may be arranged in the first direction (e.g., the x direction or −x direction) and the second direction (e.g., the y direction or −y direction) perpendicular to the first direction (e.g., the x direction or −x direction).

In an embodiment, at least one of sides of each island portion 11 may be oblique with respect to a first imaginary line IM1 connecting centers M of the island portions 11 in the first direction (e.g., the x direction or −x direction) and/or the second direction (e.g., the y direction or −y direction). The first imaginary line IM1 may be an imaginary straight line. Although it is shown in FIGS. 4A and 4B that the first imaginary line IM1 extends in the first direction (e.g., the x direction or −x direction), the first imaginary line IM1 may extend in the second direction (e.g., the y direction or −y direction). With regard to this, it is shown in FIGS. 4A and 4B that each island portion 11 includes first to fourth sides S1, S2, S3, and S4, and each of the first to fourth sides S1, S2, S3, and S4 extends in a direction oblique with respect to the first imaginary line IM1 connecting the centers M of the island portions 11.

Hereinafter, in an embodiment, although each of the island portions 11 is a quadrilateral and includes four sides, the present invention is not necessarily limited thereto. In another embodiment, the island portion 11 may be a polygon such as pentagons and hexagons, or a circular shape or an elliptical shape. Hereinafter, to distinguish one side of the island portion 11 from another side, the sides are referred to as the first to fourth sides S1, S2, S3, and S4.

In an embodiment, the first side S1 and the third side S3 of the island portion 11 may be parallel to each other, and cross the first imaginary line IM1. A first angle φ between the first side S1 and the first imaginary line IM1 may be greater than 45° and less than 90°. An angle between the third side S3 and the first imaginary line IM1 may be the same as the first angle φ. Because the first angle +is provided in the above range, an arrangement structure of the bridge portion 12 between the island portions 11 and the first opening CS1 may be optimized. The area of the bridge portion 12 and/or the first opening CS1 is reduced, and thus, the resolution may be improved, and the bridge portion 12 of a shape that may reduce strain may be designed. However, in the case where the first angle φ does not satisfy the above range, for example, the first angle φ is 45°, the arrangement structure of the bridge portion 12 between the island portions 11 and the first opening CS1 may be difficult to optimize.

In an embodiment, the second side S2 and the fourth side S4 of the island portion 11 may be parallel to each other. A second angle a between the second side S2 and the first imaginary line IM1 may be greater than 0° and less than 45°. An angle between the fourth side S4 and the first imaginary line IM1 may be the same as the second angle a. In the present specification, an angle between the island portion 11 and the first imaginary line IM1 may mean a smaller angle among angles formed between one side of the island portion 11 and the first imaginary line IM1.

Similarly, because the second angle a is provided in the above range, an arrangement structure of the bridge portion 12 between the island portions 11 and the first opening CS1 may be optimized. The area of the bridge portion 12 and/or the first opening CS1 is reduced, and thus, the resolution may be improved, and the bridge portion 12 of a shape that may reduce strain may be designed. However, in the case where the second angle a does not satisfy the above range, for example, the second angle a is 45°, the arrangement structure of the bridge portion 12 between the island portions 11 and the first opening CS1 may be difficult to optimize.

Island portion 11 may be connected to a plurality of bridge portions 12. The plurality of bridge portions 12 connected to one of the island portions 11 may respectively correspond to a plurality of sides of the relevant island portion 11. In an embodiment, the island portion 11 may be connected to four bridge portions 12, and the four bridge portions 12 may be respectively connected (e.g., directly connected) to four sides of the island portion 11. Two bridge portions 12 located on opposite sides with the island portion 11 therebetween in the first direction (e.g., the x direction or −x direction) may be respectively connected to two sides (e.g., the first side S1 and third side S3) of the island portion 11 which are opposite sides with the center M therebetween. The remaining two bridge portions 12 located on opposite sides with the island portion 11 therebetween in the second direction (e.g., the y direction or −y direction) may be respectively connected to other two sides (e.g., the second side S2 and fourth side S4) of the island portion 11 which are opposite sides with the center M therebetween.

Referring to FIGS. 4A and 4B, the island portions 11 may include first island portions 11a and second island portions 11b alternately disposed in the first direction (e.g. the x direction or-x direction) and the second direction (e.g., the y direction or −y direction). Each of the bridge portions 12 may connect the first island portion 11a and the second island portion 11b adjacent to each other among the island portions 11.

In an embodiment, a connection form of the one end of the bridge portion 12 and the first island portion 11a, and a connection form of another end of the bridge portion 12 and the second island portion 11b, may be different from each other. In an embodiment, one end of each of the bridge portions 12 may be connected to a corner of one side of the first island portion 11a, and another end of each of the bridge portions 12 may be connected to a portion apart from a corner of one side of the second island portion 11b. Here, when one end of the bridge portion 12 is connected to a corner of one side of the island portion 11, it may mean that the one end of the bridge portion 12 meets the corner (or the vertex) of the island portion 11. In addition, when one end of the bridge portion 12 is connected to a portion apart from a corner of one side of the island portion 11, it may mean that the one end of the bridge portion 12 does not meet the corner (or the vertex) of the island portion 11. However, the present invention is not necessarily limited thereto. In another embodiment, a connection form of the one end of the bridge portion 12 and the first island portion 11a, and a connection form of another end of the bridge portion 12 and the second island portion 11b, may be equal to each other.

In an embodiment, the bridge portions 12 may have a curved shape. As an example, as shown in FIGS. 4A and 4B, the bridge portion 12 may have a shape of a kind of circular arc. However, the present invention is not necessarily limited thereto. In another embodiment, the bridge portion 12 may have a shape having a straight portion.

It is shown in FIGS. 4A and 4B that centers of adjacent four island portions 11 are located on vertexes of first imaginary quadrilaterals BS1 and BS2 with the first opening CS1 centered. The first imaginary quadrilaterals BS1 and BS2 may have a shape such as a square, a rhombus, or a parallelogram. In an embodiment, it is shown in FIGS. 4A and 4B that the first imaginary quadrilaterals BS1 and BS2 are squares. The first island portions 11a may be disposed on a first vertex and a third vertex facing each other among vertexes of the first imaginary quadrilateral BS1, and the second island portions 11b may be disposed on a second vertex and a fourth vertex which are remaining vertexes. The second island portions 11b may be disposed on a first vertex and a third vertex facing each other among vertexes of the first imaginary quadrilateral BS2, and the first island portions 11a may be disposed on a second vertex and a fourth vertex which are remaining vertexes.

It may be understood that each of the island portions 11 shown in FIGS. 4A and 4B are obtained by rotating each of the island portions including at least one side parallel to the first direction (e.g., the x direction or −x direction) or the second direction (e.g., the y direction or −y direction) by a preset angle (e.g., an angle greater than 0° and less than 45°) with respect to the center M. As an example, each of the island portions 11 shown in FIGS. 4A and 4B may be obtained by rotating the first island portions of a quadrilateral shape (e.g., a square) by a preset angle with respect to the center M. Accordingly, at least one of sides of the island portion 11 may be oblique with respect to an imaginary line connecting the centers M of the island portions 11 in the first direction (e.g., the x direction or −x direction) and/or the second direction (e.g., the y direction or −y direction). The area of the first opening CS1 may be reduced depending on the arrangement of the island portions 11 and/or the structure of the bridge portions 12. The display panel 1 according to the embodiment shown in FIGS. 4A and 4B may provide relatively high-resolution images.

Meanwhile, in the case where the display panel 1 is stretched, the island portions 11 connected to the bridge portions 12 may rotate by a preset angle depending on a direction in which an external force is applied. The island portions 11 may rotate clockwise or counterclockwise around an axis passing through the center M of each of the island portions 11. As an example, when the display panel 1 of FIG. 4A is stretched in the first direction (e.g., the x direction and/or −x direction), the island portions 11 may rotate clockwise by a preset angle around an axis passing through the center M of each of the island portions 11. When the display panel 1 of FIG. 4B is stretched in the first direction (e.g., the x direction and/or −x direction), the island portions 11 may rotate counterclockwise by a preset angle around an axis passing through the center M of each of the island portions 11.

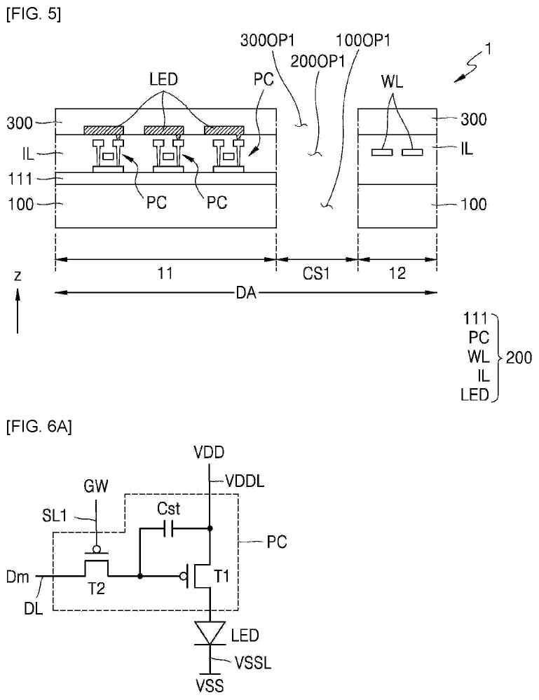

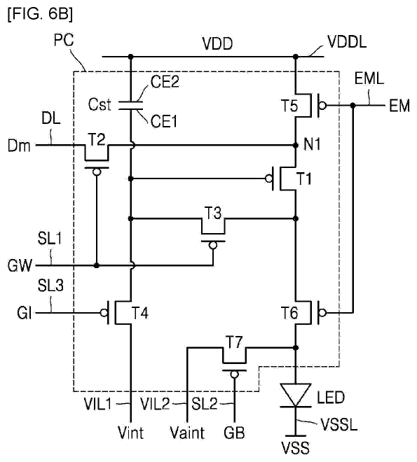

FIG. 5 is a schematic cross-sectional view of the island portion 11 and the bridge portion 12 disposed in the display area DA of the display panel 1 according to an embodiment.

Referring to FIG. 5, the island portion 11 and the bridge portion 12 disposed in the display area DA may be apart from each other with the first opening CS1 therebetween. The island portion 11 may include light-emitting elements LED and a circuit electrically connected thereto and driving the light-emitting element LED, for example, a pixel driving circuit portion PC, and the bridge portions 12 may include a wiring WL electrically connected to the pixel driving circuit portions PC disposed in each of adjacent island portions 11.

In the island portion 11, a buffer layer 111 including an inorganic insulating material may be disposed on the substrate 100, and the pixel driving circuit portion PC may be disposed on the buffer layer 111. An insulating layer IL including an inorganic insulating material and/or an organic insulating material may be disposed between the pixel driving circuit portion PC and the light-emitting element LED. The light-emitting element LED may be disposed on the insulating layer IL and electrically connected to the pixel driving circuit portion PC corresponding thereto. The light-emitting elements LED may emit light of different colors or light of the same color. In an embodiment, the light-emitting elements LED may emit red, green, and blue light. In an embodiment, the light-emitting elements LED may emit white light. In another embodiment, the light-emitting elements LED may emit red, green, blue, and white light.

The substrate 100 may include polymer resin such as polyethersulfone, polyarylate, polyetherimide, polyethylene naphthalate, polyethylene terephthalate, polyphenylene sulfide, polyimide, polycarbonate, cellulose tri acetate, cellulose acetate propionate, and the like. In an embodiment, the substrate 100 may be a single layer including the polymer resin. In another embodiment, the substrate 100 may have a multi-layered structure including a base layer and a barrier layer, wherein the base layer includes the above polymer resin and the barrier layer includes an inorganic insulating material. The substrate 100 including the polymer resin may be flexible, rollable, or bendable.

In an embodiment, although it is shown in FIG. 5 that three pixel driving circuit portions PC are disposed in each island portion 11, and three light-emitting elements LED are respectively connected to the pixel driving circuit portions PC, the present invention is not necessarily limited thereto. In another embodiment, the number of pixel driving circuit portions PC and the number of light-emitting elements LED disposed in the island portion 11 may be one, two, or four or more.

An encapsulation layer 300 may be disposed on the light-emitting element LED and may protect the light-emitting element LED from an external force and/or moisture transmission. The encapsulation layer 300 may include an inorganic encapsulation layer and/or an organic encapsulation layer. In an embodiment, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In an embodiment, the encapsulation layer 300 may include urethane epoxy acrylate. The encapsulation layer 300 may include a photosensitive material, for example, a material such as photoresist.

When examining the bridge portion 12, the insulating layer IL including an organic insulating material may be disposed on the substrate 100. When the display panel 1 stretches, the bridge portion 12, which is relatively subject to a large amount of transformation, may not have a layer including an inorganic insulating material that is prone to cracking, unlike the island portion 11.

In an embodiment, the substrate 100 corresponding to the bridge portion 12 may have the same stack structure as a stack structure of the substrate 100 corresponding to the island portion 11. In an embodiment, the substrate 100 corresponding to the bridge portion 12 and the substrate 100 corresponding to the island portion 11 may be polymer resin layers simultaneously formed during the same process. In another embodiment, the substrate 100 corresponding to the bridge portion 12 may have a different stack structure from a stack structure of the substrate 100 corresponding to the island portion 11. In an embodiment, the substrate 100 corresponding to the bridge portion 12 may have a multi-layered structure including a base layer that includes a polymer resin and a barrier layer that includes an inorganic insulating material, and the substrate 100 corresponding to the bridge portion 12 may have a structure of a polymer resin layer in which a layer including an inorganic insulating material is absent.

As described above, the wirings WL of the bridge portion 12 may be signal lines (e.g., a gate line, a data line, and the like) for providing electrical signals, or voltage lines (e.g., a driving voltage line, an initialization voltage line, and the like) for providing voltages to transistors included in the pixel driving circuit portion PC of the island portion 11. The encapsulation layer 300 may be disposed in also the bridge portion 12. In another embodiment, the encapsulation layer 300 may not be present in the bridge portion 12.

Referring to FIGS. 4A, 4B, and 5, the substrate 100 corresponding to the island portion 11 and the substrate 100 corresponding to the bridge portion 12 may be connected to each other. In other words, the plan views shown in FIGS. 4A and 4B may be substantially the same as the plan view of the substrate 100 in FIG. 5. In other words, the substrate 100 may include a region corresponding to the island portion 11, a region corresponding to the bridge portion 12, and an opening 100OP1 having the same shape as a shape of the first opening CS1.

Similarly, the encapsulation layer 300 corresponding to the island portion 11 and the encapsulation layer 300 corresponding to the bridge portion 12 may be connected to each other. As an example, the plan views shown in FIGS. 4A and 4B may be substantially the same as the plan view of the encapsulation layer 300. In other words, the encapsulation layer 300 may include a region corresponding to the island portion 11, a region corresponding to the bridge portion 12, and an opening 300OP1 having the same shape as a shape of the first opening CS1.

A circuit-light-emitting element layer 200 between the substrate 100 and the encapsulation layer 300 may include the buffer layer 111, the pixel driving circuit portion PC, the wiring WL, the insulating layer IL, and the light-emitting element LED. Similar to the substrate 100, the plan views shown above in FIGS. 4A and 4B may be substantially the same as the plan view of the circuit-light-emitting element layer 200. In other words, the circuit-light-emitting element layer 200 may include an opening 200OP1 having the same shape as a shape of the first opening CS1.

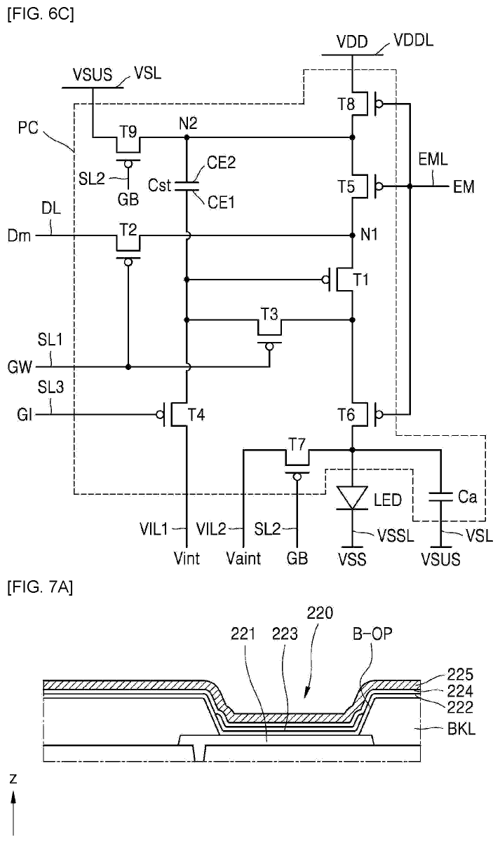

FIGS. 6A to 6C are equivalent circuit diagrams of the light-emitting element LED and the pixel driving circuit portion PC electrically connected thereto of the display panel 1 according to an embodiment.

Referring to FIG. 6A, the light-emitting element LED corresponding to a sub-pixel may be electrically connected to the pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may provide a first scan signal GW1 to a gate electrode of the second transistor T2. The second transistor T2 is configured to transfer a data signal Dm to the first transistor T1 according to a first scan signal GW1 input from the first scan line SL1, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected to the first voltage line VDDL and the storage capacitor Cst. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode of the light-emitting element LED may be electrically connected to the first transistor T1, and a second electrode may be electrically connected to a second voltage line VSSL supplying a second power voltage VSS.

Although it is shown in FIG. 6A that the pixel driving circuit portion PC includes two transistors and one storage capacitor, the pixel driving circuit portion PC may include three or more transistors in another embodiment.

Referring to FIG. 6B, the pixel driving circuit portion PC may include the first transistor T1, the second transistor T2, a third transistor T3, a fourth transistor T4, a fifth transistor T5, a sixth transistor T6, a seventh transistor T7, and the storage capacitor Cst.

The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include first and second initialization voltage lines VIL1 and VIL2, and the first voltage line VDDL.

The first voltage line VDDL may transfer the first power voltage VDD to the first transistor T1. The first initialization voltage line VIL1 may transfer a first initialization voltage Vint to the pixel driving circuit portion PC, wherein the first initialization voltage Vint initializes the first transistor T1. The second initialization voltage line VIL2 may transfer a second initialization voltage Vaint to the pixel driving circuit portion PC, wherein the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 is a driving transistor, and receives a data signal Dm and supplies the driving current to the light-emitting element LED according to a switching operation of the second transistor T2.

The second transistor T2 is a data-write transistor and is electrically connected to the first scan line SL1 and the data line DL. The second transistor T2 is electrically connected to the first voltage line VDDL through the fifth transistor T5. The second transistor T2 is turned on according to a first scan signal GW transferred through the first scan line SL1, and performs a switching operation of transferring a data signal Dm to a first node N1, the data signal Dm being transferred through the data line DL.

The third transistor T3 is electrically connected to the first scan line SL1 and electrically connected to the light-emitting element LED through the sixth transistor T6. The third transistor T3 may be turned on according to a first scan signal GW to diode-connect the first transistor T1, wherein the first scan signal GW is transferred through the first scan line SL1.

The fourth transistor T4 is a first initialization transistor and is electrically connected to the third scan line SL3 and the first initialization voltage line VIL1. The fourth transistor T4 may be turned on according to a third scan signal GI to initialize a voltage of the gate electrode of the first transistor T1 by transferring the first initialization voltage Vint to the gate electrode of the first transistor T1, wherein the first initialization voltage Vint is from the first initialization voltage line VIL1, and the third scan signal GI is transferred through the third scan line SL3. The third scan signal GI may correspond to a first scan signal of another pixel driving circuit portion disposed in a previous row of the relevant pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and may transfer the second initialization voltage Vaint from the second initialization voltage line VIL2 to the first electrode of the light-emitting element LED, thereby initializing the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 6C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include the first and second initialization voltage lines VIL1 and VIL2, a sustain voltage line VSL, and the first voltage line VDDL.

The first voltage line VDDL may transfer the first power voltage VDD to the first transistor T1. The first initialization voltage line VIL1 may transfer a first initialization voltage Vint to the pixel driving circuit portion PC, wherein the first initialization voltage Vint initializes the first transistor T1. The second initialization voltage line VIL2 may transfer a second initialization voltage Vaint to the pixel driving circuit portion PC, wherein the second initialization voltage Vaint initializes the first electrode of the light-emitting element LED. The sustain voltage line VSL may provide a sustain voltage VSUS to a second node N2, for example, the second electrode CE2 of the storage capacitor Cst during an initialization section and a data-write section.

The first transistor T1 may be electrically connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED according to a switching operation of the second transistor T2.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, wherein the data signal Dm is transferred through the data line DL.

The third transistor T3 is electrically connected to the first scan line SL1 and electrically connected to the light-emitting element LED through the sixth transistor T6. The third transistor T3 may be turned on according to a first scan signal GW to compensate for a threshold voltage of the first transistor T1 by diode-connecting the first transistor T1, wherein the first scan signal GW is transferred through the first scan line SL1.

The fourth transistor T4 is electrically connected to the third scan line SL3 and the first initialization voltage line VIL1, turned on according to a third scan signal GI transferred through the third scan line SL3, and initializes a voltage of the gate electrode of the first transistor T1 by transferring the first initialization voltage Vint from the first initialization voltage line VIL1 to the gate electrode of the first transistor T1. The third scan signal GI may correspond to a first scan signal of another pixel driving circuit portion disposed in a previous row of the relevant pixel driving circuit portion PC. The fifth transistor T5, the sixth transistor T6, and the eighth transistor T8 may be electrically connected to the emission control line EML, simultaneously turned on according to an emission control signal EM transferred through the emission control line EML, and may form a current path such that the driving current flows in a direction from the first voltage line VDDL to the light-emitting element LED.

The seventh transistor T7 is a second initialization transistor and may be electrically connected to the second scan line SL2, the second initialization voltage line VIL2, and the sixth transistor T6. The seventh transistor T7 is turned on according to a second scan signal GB transferred through the second scan line SL2, and transfers the second initialization voltage Vaint from the second initialization voltage line VIL2 to the first electrode of the light-emitting element LED, thereby initializing the first electrode of the light-emitting element LED.

The ninth transistor T9 may be electrically connected to the second scan line SL2, the second electrode CE2 of the storage capacitor Cst, and the sustain voltage line VSL. The ninth transistor T9 is turned on according to a second scan signal GB transferred through the second scan line SL2 and may transfer the sustain voltage VSUS to the second node N2, for example, the second electrode CE2 of the storage capacitor Cst during the initialization section and the data-write section.

Each of the eighth transistor T8 and the ninth transistor T9 may be electrically connected to the second node N2, for example, the second electrode CE2 of the storage capacitor Cst. In an embodiment, during the initialization section and the data-write section, the eighth transistor T8 may be turned off and the ninth transistor T9 may be turned on. During an emission section, the eighth transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display panel depending on a voltage drop of the first voltage line VDDL may be improved.

The storage capacitor Cst includes a first electrode CE1 and a second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may prevent a black brightness from rising when the sixth transistor T6 is turned off by storing and maintaining a voltage corresponding to a voltage difference between the first electrode of the light-emitting element LED and the sustain voltage line VSL while the seventh transistor T7 and the ninth transistor T9 are turned on.

FIG. 7A is a schematic cross-sectional view of a light-emitting element of a display panel according to an embodiment.

Referring to FIG. 7A, the light-emitting element according to an embodiment of the present invention may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may include an opening B-OP overlapping the central portion of the first electrode 221.

The first electrode 221 may include a conductive oxide such as indium tin oxide (ITO), indium zinc oxide (IZO), zinc oxide (ZnO), indium oxide (In2O3), indium gallium oxide (IGO), or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the first electrode 221 may further include a layer on/under the reflective layer, the layer including ITO, IZO, ZnO, AZO, or In2O3.

The emission layer 223 may include a polymer organic material or a low-molecular weight organic material emitting light having a preset color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. As an example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 225 may further include a layer on the (semi) transparent layer, the layer including ITO, IZO, ZnO, AZO, or In2O3.

FIG. 7B is a schematic cross-sectional view of a light-emitting element of a display panel according to an embodiment.

Referring to FIG. 7B, the light-emitting element according to an embodiment of the present invention may be an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed on the same layer.

In an embodiment, the first semiconductor layer 231 may include a p-type semiconductor layer. The p-type semiconductor layer may be selected from among semiconductor materials having a composition formula of InxAlyGa1-x-yN (0≤x≤1, 0≤y≤1, 0≤x+y≤1), such as GaN, AlN, AlGaN, InGaN, InN, InAlGaN, AlInN, and the like, and may be doped with a p-type dopant such as Mg, Zn, Ca, Sr, or Ba.

The second semiconductor layer 232 may include, for example, an n-type semiconductor layer. The n-type semiconductor layer may be selected from among semiconductor materials having a composition formula of InxAlyGa1-x-yN (0≤x≤1, 0≤y≤1, 0≤x+y≤1), such as GaN, AlN, AlGaN, InGaN, InN, InAlGaN, AlInN, and the like, and may be doped with an n-type dopant such as Si, Ge, or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InxAlyGa1-x-yN (0≤x≤1, 0≤y≤1, 0≤x+y≤1), and be formed in a single quantum-well structure or a multi quantum-well structure (MQW). In addition, the intermediate layer 233 may include a quantum-wire structure or a quantum-dot structure.

Although it is described in FIG. 7B that the first semiconductor layer 231 includes a p-type semiconductor layer, and the second semiconductor layer 232 includes an n-type semiconductor layer, the present invention is not limited thereto. In another embodiment, the first semiconductor layer 231 may include an n-type semiconductor layer, and the second semiconductor layer 232 may include a p-type semiconductor layer.

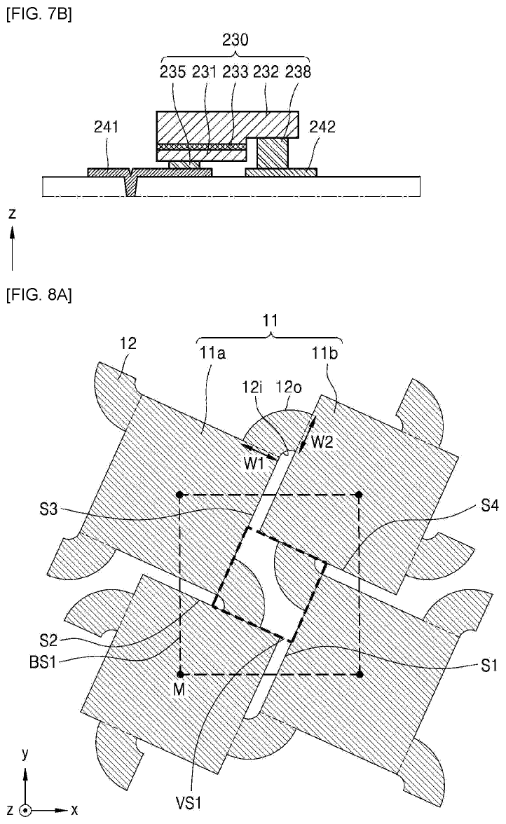

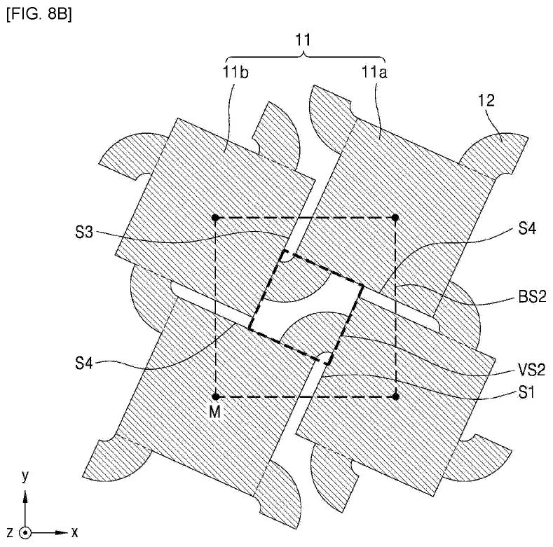

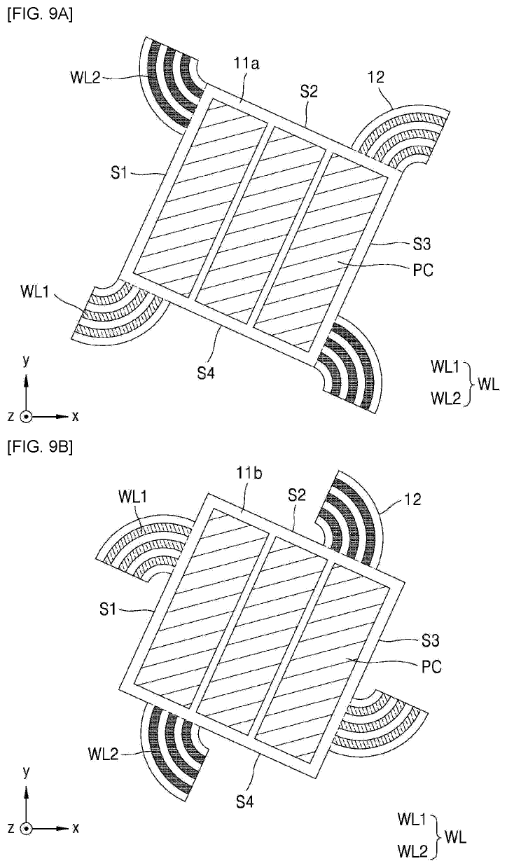

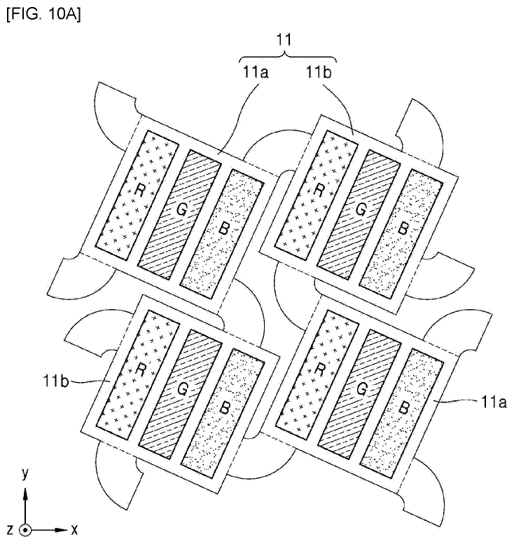

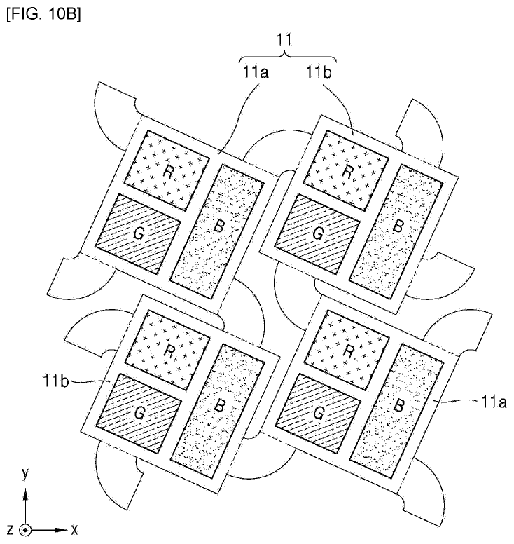

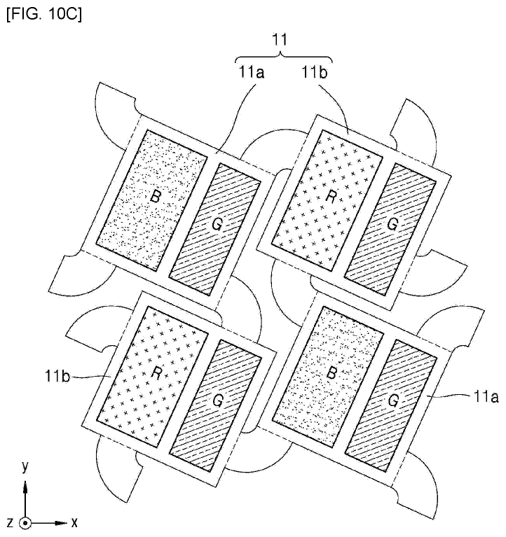

FIGS. 8A and 8B are plan views of the island portions 11 and the bridge portions 12 disposed in the display area DA of the display panel 1 of FIG. 4A. FIG. 8A shows the island portions 11 and the bridge portions 12 connected thereto, disposed in the first imaginary quadrilateral BS1, and FIG. 8B shows the island portions 11 and the bridge portions 12 connected thereto, disposed in the first imaginary quadrilateral BS2.

Referring to FIGS. 8A and 8B, the island portions 11 may include first island portions 11a and second island portions 11b alternately disposed in the first direction (e.g. the x direction or −x direction) and the second direction (e.g., the y direction or −y direction). Each of the bridge portions 12 may connect the first island portion 11a and the second island portion 11b adjacent to each other among the island portions 11.

One sides of adjacent island portions 11 may be disposed side-by-side. As an example, a first side S1 of one first island portion 11a may be parallel to a third side S3 of another second island portion 11b adjacent in the first direction (e.g., the −x direction), and a third side S3 of the one first island portion 11a may be parallel to a first side S1 of another second island portion 11b adjacent in the first direction (e.g., the x direction). In this case, the bridge portion 12 may not be disposed between the first side S1 of the first island portion 11a and the third side S3 of the second island portion 11b disposed parallel to each other, and between the third side S3 of the first island portion 11a and the first side S1 of the second island portion 11b disposed parallel to each other.

In addition, a second side S2 of one first island portion 11a may be parallel to a fourth side S4 of another second island portion 11b adjacent in the second direction (e.g., the y direction), and a fourth side S4 of the one first island portion 11a may be parallel to a second side S2 of another second island portion 11b adjacent in the second direction (e.g., the −y direction). In this case, the bridge portion 12 may not be disposed between the second side S2 of the first island portion 11a and the fourth side S4 of the second island portion 11b disposed parallel to each other, and between the fourth side S4 of the first island portion 11a and the second side S2 of the second island portion 11b disposed parallel to each other.

The bridge portion 12 may connect one sides of two island portions 11 adjacent to each other, in which one side of one island portion 11 connected to one end of the bridge portion 12, and one side of the other island portion 11 connected to another end of the bridge portion 12 may be disposed in directions crossing each other. In an embodiment, one side of one island portion 11 connected to one end of the bridge portion 12, and one side of the other island portion 11 connected to another end of the bridge portion 12 may be disposed perpendicular to each other. As an example, the bridge portion 12 may connect the first side S1 of the first island portion 11a and the fourth side S4 of the second island portion 11b adjacent to the second direction (e.g., the y direction or −y direction), connect the third side S3 of the first island portion 11a and the second side S2 of the second island portion 11b adjacent to the second direction (e.g., the y direction or −y direction), connect the second side S1 of the first island portion 11a and the first side S1 of the second island portion 11b adjacent to the first direction (e.g., the x direction or −x direction), or connect the fourth side S4 of the first island portion 11a and the third side S3 of the second island portion 11b adjacent to the first direction (e.g., the x direction or −x direction).

The bridge portion 12 may be disposed within the first imaginary quadrilaterals BS1 and BS2 having the centers M of four adjacent island portions 11 as vertexes. The bridge portion 12 connecting the first island portion 11a and the second island portion 11b adjacent to each other in the second direction (e.g., the y direction or −y direction) may be disposed within the first imaginary quadrilateral BS1. The bridge portion 12 connecting the first island portion 11a and the second island portion 11b adjacent to each other in the first direction (e.g., the x direction or −x direction) may be disposed within the first imaginary quadrilateral BS2. Two bridge portions 12 may be disposed within one first imaginary quadrilateral BS1 and BS2.

In an embodiment, the bridge portions 12 may have a curved shape. As an example, as shown in FIG. 4A, the bridge portion 12 may connect a side (e.g., the third side S3) of the first island portion 11a and a side (e.g., the second side S2) of the second island portion 11b, and extend clockwise from the side (e.g., the third side S3) of the first island portion 11a and the side (e.g., the second side S2) of the second island portion 11b. In other words, the bridge portion 12 may extend counterclockwise from a side (e.g., the second side S2) of the second island portion 11b to a side (e.g., the third side S3) of the first island portion 11a. The bridge portion 12 has a structure that extends continuously without an inflection point and may have a shape of a kind of arc.

The bridge portion 12 may include a round inner edge 12i and a round outer edge 120, and an interval between the inner edge 12i and the outer edge 120 may correspond to the width of the bridge portion 12. In an embodiment, the width of the bridge portion 12 may be substantially constant. A width W1 of one end of the bridge portion 12 connected to the first island portion 11a and a width W2 of another end of the bridge portion 12 connected to the second island portion 11b. However, the present invention is not necessarily limited thereto. In another embodiment, the width of the bridge portion 12 may be modified. The width W1 of one end of the bridge portion 12 connected to the first island portion 11a and the width W2 of another end of the bridge portion 12 connected to the second island portion 11b may be different from each other. Referring to FIG. 8A, the third side S3 of one first island portion 11a and the first side S1 of another first island portion 11a among the first island portions 11a disposed in the first imaginary quadrilateral BS1 may face each other. The fourth side S4 of one second island portion 11b and the second side S2 of another second island portion 11b among the second island portions 11b disposed in the first imaginary quadrilateral BS1 may face each other. Two sides (e.g., the first side S1 and third side S3) of the first island portions 11a facing each other and two sides (e.g., the second side S2 and fourth side S4) of the second island portions 11b facing each other within the first imaginary quadrilateral BS1 may overlap four sides of a second imaginary quadrilateral VS1. The second imaginary quadrilateral VS1 may be disposed within the first imaginary quadrilateral BS1. The second imaginary quadrilateral VS1 may have a shape such as a square, a rhombus, or a parallelogram. In an embodiment, it is shown in FIG. 8A that the second imaginary quadrilaterals VS1 is a square.

The bridge portion 12 disposed within the first imaginary quadrilateral BS1 may be disposed within the second imaginary quadrilateral VS1. That is, the bridge portion 12 connecting the first island portion 11a and the second island portion 11b adjacent to each other in the second direction (e.g., the y direction or −y direction) may be disposed within the second imaginary quadrilateral VS1.

Similarly, referring to FIG. 8B, the fourth side S4 of one first island portion 11a and the second side S2 of another first island portion 11a among the first island portions 11a disposed in the first imaginary quadrilateral BS1 may face each other. The third side S3 of one second island portion 11b and the first side S1 of another second island portion 11b among the second island portions 11b disposed in the first imaginary quadrilateral BS2 may face each other. Two sides (e.g., the second side S2 and fourth side S4) of the first island portions 11a facing each other and two sides (e.g., the first side S1 and third side S3) of the second island portions 11b facing each other within the first imaginary quadrilateral BS2 may overlap four sides of a second imaginary quadrilateral VS2. The second imaginary quadrilateral VS2 may be disposed within the first imaginary quadrilateral BS2. The second imaginary quadrilateral VS2 may have a shape such as a square, a rhombus, or a parallelogram. In an embodiment, it is shown in FIG. 8B that the second imaginary quadrilaterals VS2 is a square.

The bridge portion 12 disposed within the first imaginary quadrilateral BS2 may be disposed within the second imaginary quadrilateral VS2. That is, the bridge portion 12 connecting the first island portion 11a and the second island portion 11b adjacent to each other in the first direction (e.g., the x direction or −x direction) may be disposed within the second imaginary quadrilateral VS2.

In the display panel 1 according to an embodiment of the present invention, because the bridge portions 12 are disposed in a space (e.g., the second imaginary quadrilateral VS2) between adjacent island portions 11, the efficiency in spatial utilization may be increased and the resolution of the display panel 1 may be improved. In addition, because the bridge portion 12 is designed in a curved shape, stretchability of the display panel 1 may be improved.

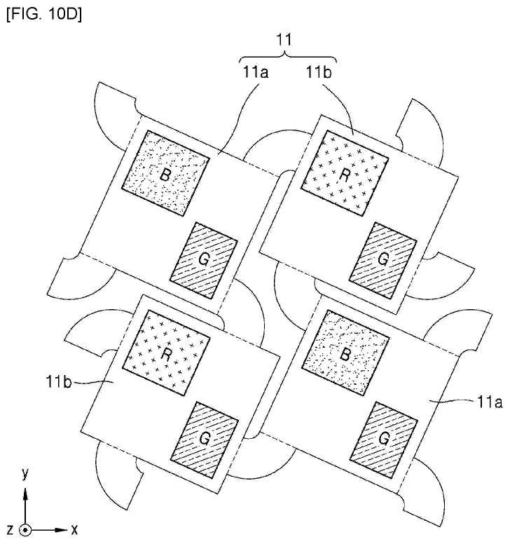

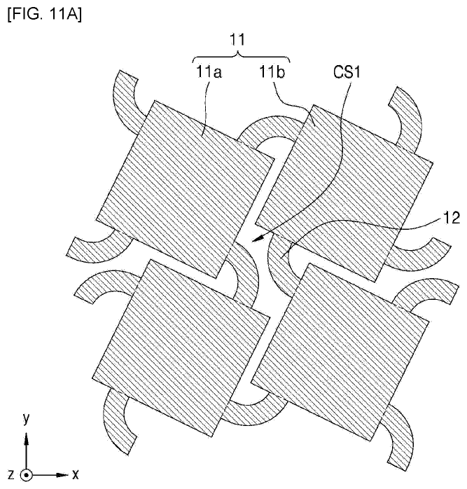

FIG. 9A is a plan arrangement view of the first island portion 11a and the bridge portions 12 connected thereto, of FIGS. 8A and 8B, and FIG. 9B is a plan arrangement view of the second island portion 11b and the bridge portions 12 connected thereto, of FIGS. 8A and 8B.

Referring to FIGS. 9A and 9B, the first island portion 11a and the second island portion 11b may include the light-emitting element and the pixel driving circuit portion PC for driving the light-emitting element. The bridge portion 12 may include the wiring WL electrically connected to the pixel driving circuit portions PC in adjacent island portions 11.

The bridge portions 12 connected to the first side S1 or the third side S3 of the first island portion 11a may include second wirings WL2 extending in the second direction (e.g., the y direction or −y direction). The bridge portions 12 connected to the second side S2 or the fourth side S4 of the first island portion 11a may include first wirings WL1 extending in the first direction (e.g., the x direction or −x direction).

The bridge portions 12 connected to the first side S1 or the third side S3 of the second island portion 11b may include the first wirings WL1 extending in the first direction (e.g., the x direction or −x direction). The bridge portions 12 connected to the second side S2 or the fourth side S4 of the second island portion 11b may include the second wirings WL2 extending in the second direction (e.g., the y direction or −y direction).

In an embodiment, it is shown in FIGS. 9A and 9B that three wirings WL are disposed in each bridge portion 12, the present invention is not necessarily limited thereto. In another embodiment, the number of wirings WL disposed in the bridge portion 12 may be one, two, or four or more.

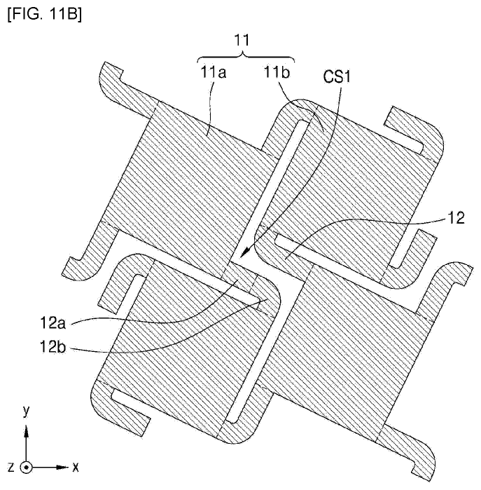

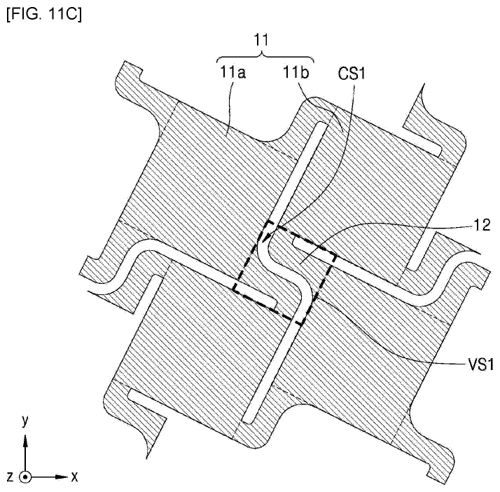

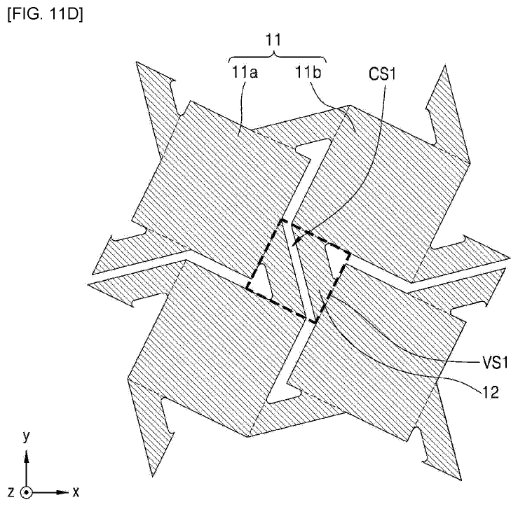

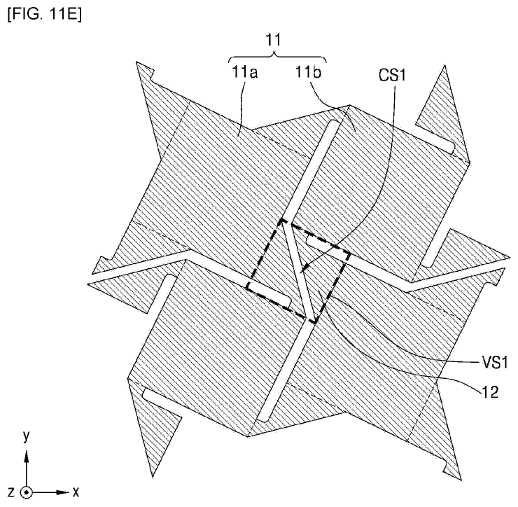

FIGS. 10A to 10D are plan arrangement views of arrangement of the pixels in the island portion 11 of the display panel 1 according to an embodiment.

Referring to FIGS. 10A and 10D, the island portion 11 is a region in which the pixels are disposed and may include the light-emitting elements respectively corresponding to the pixels. The pixels located in one island portion 11 may emit light of different colors. In an embodiment, pixels may be configured to emit red, green, or blue light. A red pixel R may be a pixel emitting red light, a green pixel G may be a pixel emitting green light, and a blue pixel B may be a pixel emitting blue light. The arrangement of the pixels in FIGS. 10A to 10D described below may represent the arrangement of the light-emitting elements respectively corresponding to the pixels. Portions shown in solid within the island portion 11 lines in FIGS. 10A to 10D may correspond to emission areas of the respective pixels.

Referring to FIGS. 10A and 10B, three pixels may be disposed in one island portion 11. One red pixel R, one green pixel G, and one blue pixel B may be disposed in one island portion 11. The arrangement of the pixels R, G, and B located in each island portion 11 may be constant.

Referring to FIG. 10A, the sizes of the red pixel R, green pixel G, and blue pixel B may be substantially the same. In one island portion 11, the red pixel R, green pixel G, and blue pixel B may be arranged in a direction from one side (e.g., the first side S1) of the island portion 11 to another side (e.g., the third side S3) facing the one side. Referring to FIG. 10B, the size of the blue pixel B may be greater than the size of the red pixel R and the size of the green pixel G. In one island portion 11, the red pixel R, green pixel G, and blue pixel B may be arranged in a direction from one side (e.g., the first side S1) of the island portion 11 to another side (e.g., the third side S3) facing the one side. In this case, the red pixel R and the green pixel G may be arranged in a direction from a side (e.g., the second side S2) crossing the one side to another side (e.g., the fourth side S4) facing the side.

Referring to FIGS. 10C and 10D, two pixels may be disposed in one island portion 11. In an embodiment, one red pixel R and one green pixel G may be disposed, or one blue pixel B and one green pixel G may be disposed in one island portion 11. As an example, one blue pixel B and one green pixel G may be disposed in the first island portion 11a, and one red pixel R and one green pixel G may be disposed in the second island portion 11b. The arrangement of the pixels R, G, and B located in each of the island portion 11a and the second island portion 11b may be constant.

Referring to FIG. 10C, in one island portion 11 (e.g., the first island portion 11a), the blue pixel B and the green pixel G may be arranged in a direction from one side (e.g., the first side S1) of the island portion 11 to another side (e.g., the third side S3) facing the one side. In addition, in one island portion 11 (e.g., the second island portion 11b), the red pixel R and the green pixel G may be arranged in a direction from one side (e.g., the first side S1) of the island portion 11 to another side (e.g., the third side S3) facing the one side.

Referring to FIG. 10D, in one island portion 11 (e.g., the first island portion 11a), the blue pixel B and the green pixel G may be arranged in a direction from one corner (e.g., a corner where the first side S1 meets the second side S2) of the island portion 11 to another corner (e.g., a corner where the third side S3 meets the fourth side S4) facing the one corner of the island portion 11. In addition, in one island portion 11 (e.g., the second island portion 11b), the red pixel R and the green pixel G may be arranged in a direction from one corner (e.g., a corner where the first side S1 meets the second side S2) of the island portion 11 to another corner (e.g., a corner where the third side S3 meets the fourth side S4) facing the one corner of the island portion 11.

A pixel arrangement structure of FIGS. 10A to 10D are example arrangement structures, and the present invention is not limited thereto. An arrangement structure of the pixels located in the island portion 11 may be variously modified. In another embodiment, the pixels located in the island portion 11 may emit light of a color other than red, green, and blue light, and the number of pixels located in one island portion 11 may be variously modified. The size of the pixels located in the island portion 11 may be variously modified.

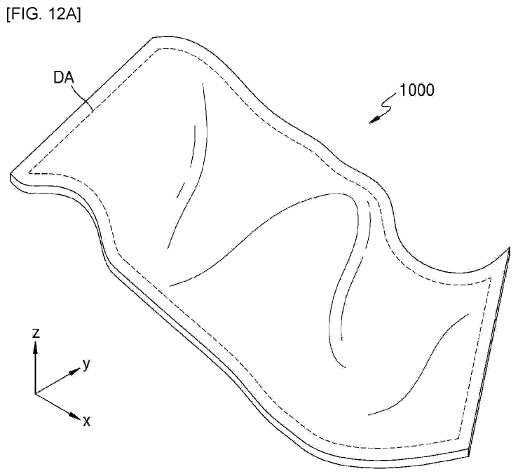

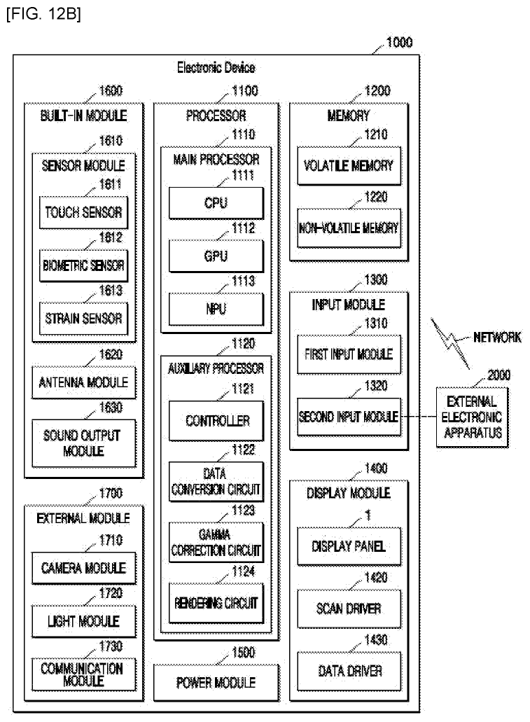

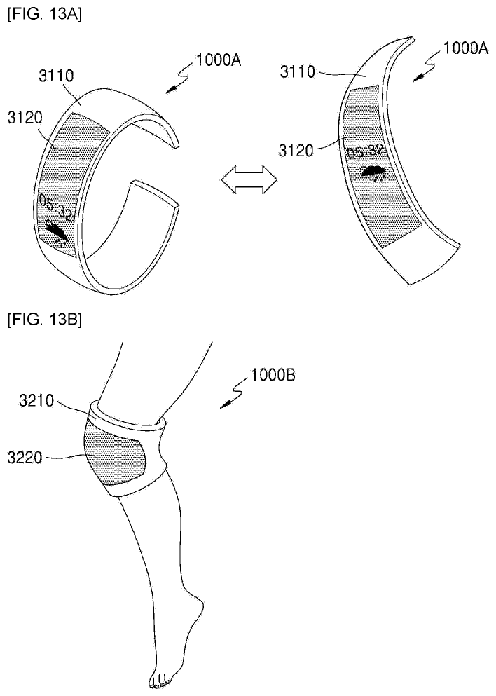

FIGS. 11A to 11E are plan views of a portion of the display area of the display panel according to an embodiment. FIGS. 11A to 11E are modified embodiments of FIG. 8A, and differences are mainly described below and repeated descriptions are omitted.

Referring to FIG. 11A, in an embodiment, one end of each of the bridge portions 12 may be connected to a portion apart from a corner of one side of the first island portion 11a, and another end of each of the bridge portions 12 may be connected to a portion apart from a corner of one side of the second island portion 11b.

In an embodiment, the bridge portions 12 may have a curved shape. As an example, as shown in FIG. 11A, the bridge portion 12 may have a shape of a kind of circular arc.

Referring to FIG. 11B, in an embodiment, one end of each of the bridge portions 12 may be connected to a corner of one side of the first island portion 11a, and another end of each of the bridge portions 12 may be connected to a corner of one side of the second island portion 11b.

In an embodiment, the bridge portion 12 may include a straight portion 12a and a curved portion 12b. The straight portion 12a may be connected to the first island portion 11a, and the curved portion 12b may be connected to the second island portion 11b.

Referring to FIG. 11C, in an embodiment, one end of each of the bridge portions 12 may be connected to a corner of one side of the first island portion 11a, and another end of each of the bridge portions 12 may be connected to a corner of one side of the second island portion 11b.

In an embodiment, the first opening CS1 may be provided in a slit shape. A portion of the first opening CS1 disposed between the bridge portions 12 within the second imaginary quadrilateral VS1 may have a curved shape with an inflection point. The portion of the first opening CS1 may have a shape of an approximate “letter S”.

Referring to FIG. 11D, in an embodiment, one end of each of the bridge portions 12 may be connected to a portion apart from a corner of one side of the first island portion 11a, and another end of each of the bridge portions 12 may be connected to a corner of one side of the second island portion 11b.

In an embodiment, the bridge portion 12 may have an approximate straight shape. A portion of the first opening CS1 disposed between the bridge portions 12 within the second imaginary quadrilateral VS1 may have a straight shape. The portion of the first opening CS1 may have an oblique shape.

Referring to FIG. 11E, in an embodiment, one end of each of the bridge portions 12 may be connected to a corner of one side of the first island portion 11a, and another end of each of the bridge portions 12 may be connected to a corner of one side of the second island portion 11b.

In an embodiment, the first opening CS1 between the bridge portions 12 may be provided in a slit shape. A portion of the first opening CS1 disposed between the bridge portions 12 within the second imaginary quadrilateral VS1 may have a straight shape. The portion of the first opening CS1 may have an oblique shape.

The display panel 1 according to the above embodiments may be used in various electronic apparatuses that may display images. Here, the electronic apparatuses represent apparatuses having a function that may display preset images using electricity.

FIG. 12A is a schematic perspective view of an electronic apparatus 1000 including a display panel according to an embodiment, and FIG. 12B is a schematic block diagram of the electronic apparatus 1000 including the display panel according to an embodiment.

Referring to FIG. 12A, the electronic apparatus 1000 is freely transformed three-dimensionally, and may provide a three-dimensional image surface through the display area DA. When the electronic apparatus 1000 is freely transformed three-dimensionally, it is distinguished from an operation of an electronic apparatus having a rollable display panel such as a case where a portion of a rolled-up display area is visible to a user and then another portion of the rolled-up display area is unfolded so that the entire display area is visible to the user (or a case where the entire unfolded display area is visible to the user and then the display area is rolled-up so that only a portion of the display area is visible to the user). The electronic apparatus 1000 according to embodiments of the present invention may represent transformation such as a case where the area of the entire display area DA increases or decreases again while the electronic apparatus 1000 is transformed in the x direction, y direction, and/or z direction.

Referring to FIG. 12B, the electronic apparatus 1000 may include a processor 1100, a memory 1200, an input module 1300, a display module 1400, a power module 1500, a built-in module 1600, and an external module 1700. According to an embodiment, in the electronic apparatus 1000, at least one of the elements may be omitted, or one or more other elements may be added. According to an embodiment, some (e.g., built-in module 1600) of the elements may be integrated into another element (e.g., display module 1400).

The processor 1100 may control at least one other element (e.g., hardware or software element) of the electronic apparatus 1000 connected to the processor 1100 by executing software, and perform various data processes or operations. According to an embodiment, as at least some of data processes or operations, the processor 1100 may store commands or data received from another element (e.g., the input module 1300, a sensor module 1610, or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals required for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1000, a user's settings, or the like, or convert image data to reduce power consumption or compensate for an afterimage. The gamma correction circuit 1123 may convert image data, a gamma reference voltage, or the like such that images displayed by the electronic apparatus 1000 have desired gamma characteristics. The rendering circuit 1124 may receive image data from the controller 1121, and render the image data by taking into account the pixel configuration of the display panel 1 applied to the electronic apparatus 1000. At least one of the data conversion circuit 1122, the gamma correction circuit 1123, and the rendering circuit 1124 may be integrated into another element (e.g., main processor 1110 or controller 1121). In an embodiment, the auxiliary processor 1120 may be integrated into a data driver 1430.

The memory 1200 may store various data and input data or output data for commands related thereto, wherein the various data are used by at least one element (e.g., the processor 1100 or the sensor module 1610) of the electronic apparatus 1000. The memory 1200 may include at least one of the volatile memory 1210 and the non-volatile memory 1220.

The input module 1300 may receive commands or data from the outside (e.g., a user or an external electronic apparatus 2000) of the electronic apparatus 1000, wherein the commands or data are to be used by the element (e.g., the processor 1100, the sensor module 1610, or a sound output module 1630) of the electronic apparatus 1000.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, or a pen (e.g., a passive pen or active pen). The first input module 1310 may include a mechanical input means such as buttons, a dome switch, a jog wheel, a jog switch, and the like, or a touch input means located on the lower surface or the lateral surface of the electronic apparatus 1000. The touch input means may include a touchscreen layer of the display panel 1.

The second input module 1320 may be connected to various kinds of external electronic apparatuses 2000 connected to the electronic apparatus 1000 via wires or wirelessly. In an embodiment, the second input module 1320 may include a high definition multimedia interface (HDMI), a universal serial bus (USB) interface, a secure digital (SD) card interface, or an audio interface. The second input module 1320 may include a connector that may physically connect the electronic apparatus 1000 to the external electronic apparatus 2000, wherein the connector includes an HDMI connector, a USB connector, an SD card connector, or an audio connector (e.g., a headphone connector). The electronic apparatus 1000 may perform appropriate control related to the connected external electronic apparatus 2000 in response to the external electronic apparatus 2000 being connected to the second input module 1320. The display module 1400 provides a user with visual information. The display module 1400 may include the display panel 1, a scan driver 1420, and the data driver 1430.

The display panel 1 displays (outputs) information processed by the electronic apparatus 1000. The display panel 1 may display execution screen information of an application driven in the electronic apparatus 1000, or user interface (UI) and graphic user interface (GUI) information corresponding to the execution screen information.

The scan driver 1420 may be mounted on the display panel 1 as a driving chip. Alternatively, the scan driver 1420 may be directly formed on the display panel 1. As an example, the scan driver 1420 may include an amorphous silicon thin-film transistor (TFT) gate driver circuit (ASG), a low temperature polycrystalline silicon (LTPS) TFT gate driver circuit, or an oxide semiconductor TFT gate (OSG) driver circuit embedded in the display panel 1. The scan driver 1420 receives control signals from the controller 1121 and outputs scan signals to the display panel 1 in response to control signals.

The display panel 1 may further include an emission control driver. The emission control driver outputs an emission control signal to the display panel 1 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display panel 1.

The data driver 1430 may be integrated into some elements of the auxiliary processor 1120. As an example, the data driver 1430 may be provided in a timing controller embedded driver integrated circuit (IC) including the controller 1121.

The power module 1500 supplies power to the elements of the electronic apparatus 1000. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1000.

The electronic apparatus 1000 may further include the built-in module 1600 and the external module 1700. The built-in module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display panel 1, and a touch sensor driver. The sensor module 1610 may sense an input due to a user's body or an input due to a pen, and generate an electrical signal or a data value corresponding to the input. The sensor module 1610 may include at least one of a touch sensor 1611, a biometric sensor 1612, and a strain sensor 1613. The touch sensor 1611 may generate a data value corresponding to coordinate information of an input due to a user's body (e.g., fingers and the like) or an input due to a pen. The touch sensor 1611 may generate, as data values, changes in electrostatic capacity, pressure, or electromagnetism due to an input.

The biometric sensor 1612 may generate data values that recognize a portion of the user's body (e.g., fingerprints, irises, face, and the like) or generate data values corresponding to body information (e.g., blood pressure, moisture, heart rate, body composition, and the like). The biometric sensor 1612 may use an optical method, an ultrasonic method, or a capacitive method.

The strain sensor 1613 may include layers, patterns or wirings in which a measurable physical quantity changes according to the stretching of the display panel 1. As an example, the strain sensor 1613 may include wirings in which a pressure, a resistance, and/or a capacitance changes due to the stretching of the display panel 1. In another embodiment, the strain sensor 1613 may include optical layers or optical patterns in which a transmittance and/or reflectivity changes due to the stretching of the display panel 1.

The electronic apparatus 1000 may improve the quality of images implemented by the display panel 1 or control the display panel 1 based on physical quantity changes due to the stretching of the display panel 1 measured by the strain sensor 1613. Control operations of the display panel 1 may include operations such as displaying an operation image for protecting the display panel 1, blocking voltages for driving the display panel 1, or stopping a stretching operation of the display panel 1. In an embodiment, at least one of the touch sensor 1611, the biometric sensor 1612, and a digitizer, and the strain sensor 1613 may be built into the display panel 1. As an example, at least one of the touch sensor 1611, the biometric sensor 1612, and the strain sensor 1613 may be formed during a process that is successive to the process of forming the pixel driving circuit portion and/or the light-emitting element of the display panel 1. Accordingly, the display panel 1 may serve as one of the input modules 1300 that provide an input interface between the electronic apparatus 1000 and a user, and simultaneously, serve as the display module 1400 that provides an output interface between the electronic apparatus 1000 and a user.

In an embodiment, at least two of the touch sensor 1611, the biometric sensor 1612, and the strain sensor 1613 may be formed to be integrated in one sensing panel through the same process. In an embodiment, although the sensing panel may be disposed between the display panel 1 and a window cover disposed on a front surface of the display panel 1, the present invention is not limited thereto.

The antenna module 1620 may include at least one antenna for transmitting signals or power to the outside or receiving signals or power from the outside. In an embodiment, the communication module 1730 may transmit signals to an external electronic apparatus or receive signals from an external electronic apparatus through an antenna suitable for a communication method. An antenna pattern of the antenna module 1620 may be integrated in one element (e.g., the display panel 1) of the display module 1400 or the biometric sensor 1612.

The sound output module 1630 is a device for outputting sound signals to the outside of the electronic apparatus 1000, and may output sound data received from the communication module 1730 or stored in the memory 1200 during call signal reception, a communication mode or recording mode, a voice recognition mode, a broadcasting reception mode, and the like. The sound output module 1630 may output sound signals related to a function (e.g., call signal reception tone, a message reception tone, and the like) performed by the electronic apparatus 1000. The sound output module 1630 may include a receiver and a speaker. At least one of the receiver and the speaker may be a sound generator that is attached on the backside of the display panel 1 and vibrates the display panel 1 to output sounds. The sound generator may be a piezoelectric element or a piezoelectric actuator that contracts and expands according to electrical signals, or an exciter that generates magnetic force by using a voice coil to vibrate the display panel 1.

The camera module 1710 may capture still images and moving images. In an embodiment, the camera module 1710 may include at least one lens, an image sensor, or an image signal processor. The camera module 1710 may further include an infrared camera that may measure whether a user is present, a user's position, a user's gaze, and the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and the like. The light module 1720 may include a light-emitting diode or a xenon lamp. The light module 1720 may emit light of a single color or multiple colors to the front side or backside of the electronic apparatus 1000. The light module 1720 may operate in cooperation with the camera module 1710 or independently.

The communication module 1730 may establish a wired or wireless communication channel between the electronic apparatus 1000 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using at least one of a wireless LAN) (WLAN), wireless-fidelity (Wi-Fi), Wi-Fi direct, and digital living network alliance (DLNA) technologies. In addition, the communication module 1730 may support short-range communication using at least one of Bluetooth ™, RFID radio frequency identification (RFID), infrared data association (IrDA), ultra-wideband (UWB), ZigBee, near field communication (NFC), Wi-Fi, Wi-Fi Direct, and wireless universal serial bus (USB) technologies. The above-described various kinds of communication modules 1730 may be implemented in one chip or respectively implemented as separate chips.

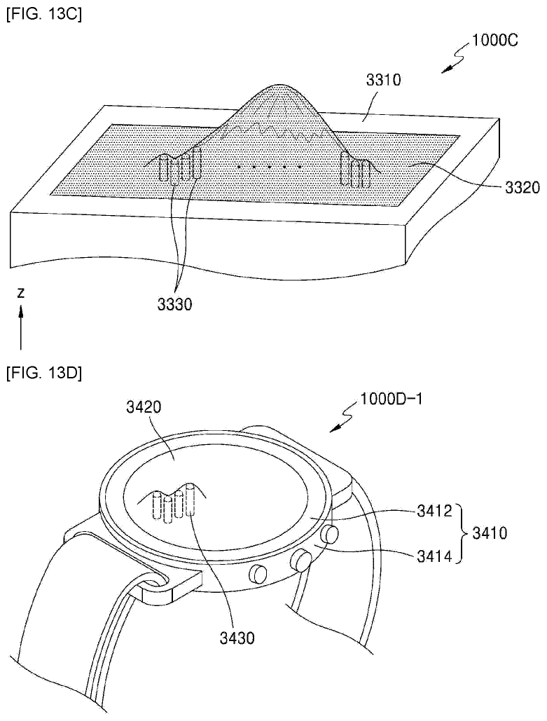

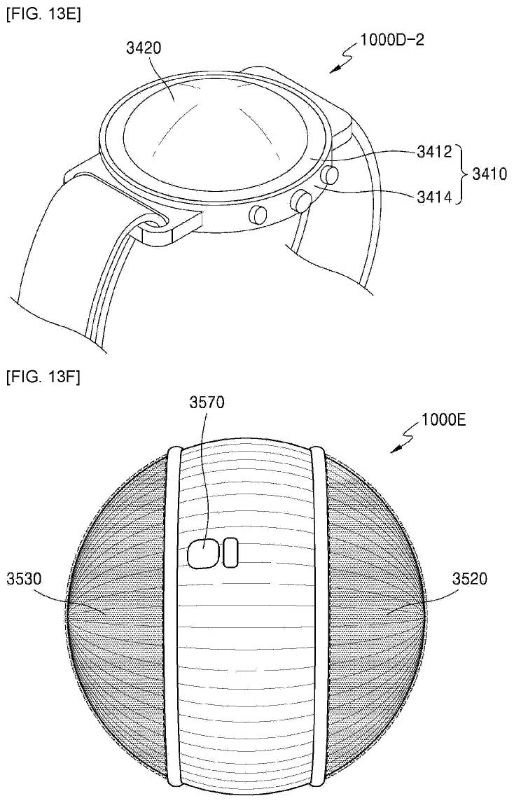

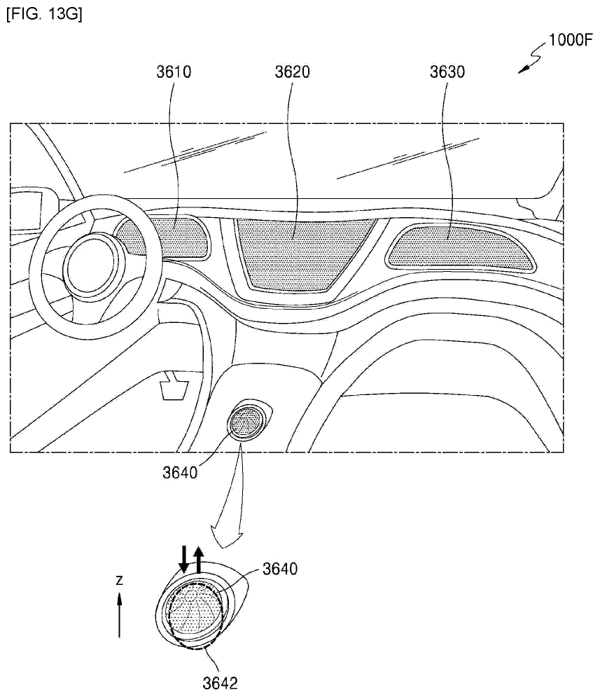

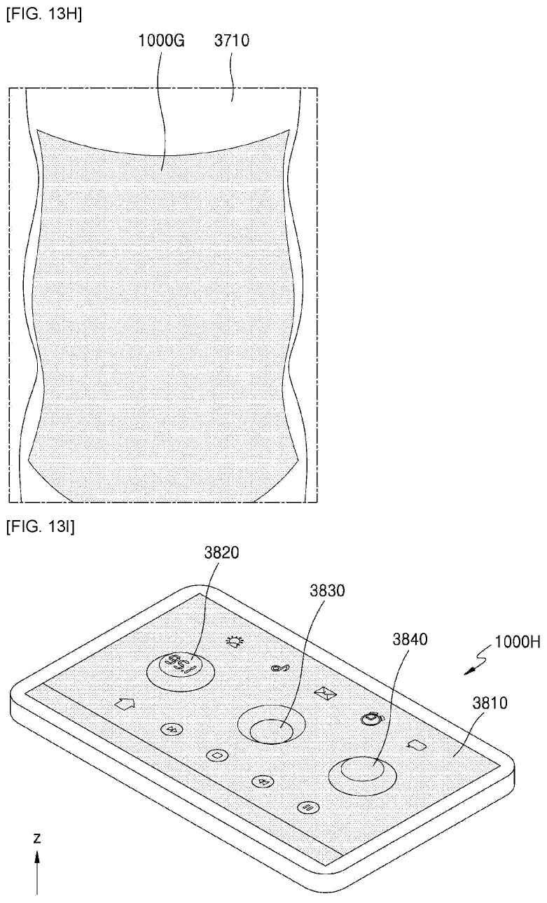

FIGS. 13A to 131 are schematic perspective views of an electronic apparatus including a display panel 1 according to an embodiment of the present invention.

Referring to FIG. 13A, the display panel according to an embodiment may be utilized in a wearable electronic apparatus 1000A that may be worn on a portion of a user's body. The wearable electronic apparatus 1000A may include a body portion 3110 and a display portion 3120 provided to the body portion 3110. The display panel according to embodiments of the present invention may be used as the display portion 3120 of the wearable electronic apparatus 1000A. As shown in FIG. 13A, the wearable electronic apparatus 1000A may be transformed. In an embodiment, the wearable electronic apparatus 1000A may be used as a smartwatch or a smartphone according to a user's selection.

FIG. 13B shows a medical electronic apparatus 1000B. In an embodiment, the medical electronic apparatus 1000B may include a body portion 3210 and a light-emitting portion 3220. The display panel according to embodiments of the present invention may be used as the light-emitting portion 3220 of the medical electronic apparatus 1000B. The light-emitting portion 3220 may emit light (e.g., infrared rays, visible rays, and the like) in a preset wavelength band to a patient's body. In an embodiment, the body portion 3210 may include a stretchable fiber material and have a structure that may be worn on the body of a user.

FIG. 13C shows an educational electronic apparatus 1000C. In an embodiment, the educational electronic apparatus may include a display portion 3320 provided inside a housing 3310. The display portion 3320 may be used as the display panel according to the embodiments of the present invention. An image such as a sea with crashing waves, a snow-covered mountain, or a volcano with flowing lava can be provided through the display portion 3320, and in this case, the display portion 3320 may be stretched in a height direction (e.g., z direction) to reflect the height of the wave, mountain, or volcano. In an embodiment, a portion of the display portion 3320 may be configured to sequentially change its height in a direction in which the lava flows, thereby showing the movement of the lava three dimensionally. The educational electronic apparatus 1000C may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 13C describes the educational electronic apparatus 1000C, the purpose thereof is not limited thereto as far as the educational electronic apparatus provides preset image information.

FIGS. 13D and 13E show the display panel is used in wearable electronic apparatuses 1000D-1 and 1000D-2 such as a smartwatch.

In an embodiment, as shown in FIG. 13D, because the display panel corresponding to the display portion 3420 of the electronic apparatus 1000D-1 is stretchable three-dimensionally, the display panel may provide, to a user, various haptic information in addition to visual information through images. In an embodiment, the electronic apparatus 1000D-1 may provide haptic information, such as Braille display for the visually impaired or tactile stimulation linked to an image, by using a plurality of pins 3430 (or stroke portions) disposed below the display portion 3420. Because the display panel forming the display portion 3420 is stretchable three-dimensionally, the display panel may provide the haptic information to a user. The electronic apparatus 1000D-1 may include the body portion 3410, wherein the body portion 3410 includes a housing 3414 in which the display panel forming the display portion 3420 and the pins 3430 (or stroke portions) are accommodated, and a frame 3412 that may be coupled to the housing 3414 with the display panel therebetween. In an embodiment, the frame 3412 may be integrally formed with the housing 3414.

The electronic apparatus 1000D-2 of FIG. 13E may include the body portion 3410 and the display portion 3420 accommodated in the body portion 3410 and providing visual information as in FIG. 13D. In an embodiment, because the display panel corresponding to the display portion 3420 is stretchable three-dimensionally, the display panel may include the display portion 3420 of a dome shape. In an embodiment, the display panel may be assembled to the body frame of a dome shape during the process of manufacturing the electronic apparatus 1000D-2, and in this case, because the display panel is stretchable three-dimensionally, the display panel may be assembled while being stretched along the shape of the hemispherical body frame.

FIG. 13F shows an electronic apparatus 1000E according to an embodiment of the present invention includes a robot. The robot may recognize a movement or object using a camera module 3570 and display preset images to a user through display portions 3520 and 3530.

In an embodiment, because the display panels according to an embodiment may be stretched in various directions as described above, the display panels may be assembled to the body frame having a hemispherical shape, and thus, the robot may include the display portions 3520 and 3530 of a hemispherical shape.

FIG. 13G shows a vehicle display apparatus 1000F as an electronic apparatus according to an embodiment of the present invention. The vehicle display apparatus 1000F may include a cluster 3610, a center information display (CID) 3620, and/or a co-driver display 3630. Because the display panel according to an embodiment may be stretched in various directions, the display panel may be used in the cluster 3610, the CID 3620, and/or the co-driver display 3630 without being restricted by the shape of an internal frame of the vehicle.

Although it is shown in FIG. 13G that the cluster 3610, the CID 3620, and/or the co-driver display 3630 are separated from each other, the present invention is not limited thereto. In another embodiment, two or more selected from the cluster 3610, the CID 3620, and the co-driver display 3630 may be integrally connected.

In an embodiment, the vehicle display apparatus 1000F may include a button 3640 that may express preset images. Referring to an enlarged view of FIG. 13H, the button 3640 of a hemispherical shape may include an object 3642 and a display panel disposed on the object 3642, wherein the object 3642 provides the feel of a button while moving in the z direction or −z-direction. In an embodiment, in the case where the object 3642 has a three-dimensionally round surface, the display panel may also have a three-dimensionally round surface.

FIG. 13H shows an electronic apparatus according to an embodiment of the present invention is an electronic apparatus 1000G for advertising or display. In an embodiment, the electronic apparatus 1000G for advertising or display may be installed on a fixed structure 3710 such as a wall or pole. In the case where the structure 3710 includes an uneven surface as shown in FIG. 13H, the electronic apparatus 1000G for advertising or display may be also disposed along the uneven surface of the structure 3710. In an embodiment, the electronic apparatus 1000G for advertising or display may be installed on the structure 3710 using a heat shrink film. FIG. 131 shows an electronic apparatus 1000H according to an embodiment of the present invention is a controller. The controller may include an image-type button. As an example, the controller may include first to third button regions 3820, 3830, and 3840 in which a portion of the display portion 3810 protrudes in the z direction or protrudes in the −z direction (or is recessed in the z direction). In an embodiment, the first and third button regions 3820 and 3840 may protrude in the z direction, and the second button region 3830 may protrude in the −z direction (or be recessed in the z direction).

While the present invention has been described with reference to an embodiment shown in the drawings, it will be understood by those of ordinary knowledge in the art that these are just examples and various changes and equivalent other embodiments may be made therefrom. Accordingly, the true technical scope of the present invention should be defined by the spirit of the appended claims.

### EXPLANATION OF REFERENCE NUMERALS DESIGNATING THE MAJOR ELEMENTS OF THE DRAWINGS

1: display panel
11: island portion
12: bridge portion
CS1: first opening
11a: first island portion
11b: second island portion

What is claimed is

1. A display panel including a display area and a non-display area outside the display area, the display panel comprising:
island portions apart from each other in a first direction and a second direction in the display area, wherein the second direction is perpendicular to the first direction; and
bridge portions respectively connecting two island portions adjacent to each other among the island portions, the bridge portions being apart from each other by openings,
wherein each of the island portions includes a first side crossing a first imaginary line passing through centers of the island portions and extending in the first direction, and
wherein an angle formed by the first side and the first imaginary line is greater than 45° and less than 90°.

2. The display panel of claim 1, wherein one of the bridge portions is disposed within a first imaginary quadrilateral having centers of four island portions adjacent to the bridge portion as vertexes.

3. The display panel of claim 1, wherein the first imaginary quadrilateral is a square.

4. The display panel of claim 1, wherein the island portions include first island portions and second island portions alternately disposed in the first direction and the second direction, and each of the bridge portions connects a first island portion and a second island portion adjacent to each other among the island portions.

5. The display panel of claim 4, wherein, in the first island portions and the second island portions, angles formed by the first side and the first imaginary line are equal to each other.

6. The display panel of claim 4, wherein one end of each of the bridge portions is connected to a corner of one side of the first island portion, and another end of each of the bridge portions is connected to a portion apart from a corner of one side of the second island portion.

7. The display panel of claim 4, wherein one side of the first island portion and one side of the second island portion connected to one of the bridge portions are disposed in directions crossing each other.

8. The display panel of claim 1, wherein the bridge portions each have a curved shape.

9. The display panel of claim 4, wherein one end of each of the bridge portions is connected to a portion apart from a corner of one side of the first island portion, and another end of each of the bridge portions is connected to a portion apart from a corner of one side of the second island portion.

10. The display panel of claim 4, wherein one end of each of the bridge portions is connected to a corner of one side of the first island portion, and another end of each of the bridge portions is connected to a corner of one side of the second island portion.

11. The display panel of claim 2, wherein the island portions include a first island portion and a second island portion respectively disposed at a first vertex and a second vertex facing each other among vertexes of the first imaginary quadrilateral and a third island portion and a fourth island portion respectively disposed at a third vertex and a fourth vertex facing each other,
wherein, within the first imaginary quadrilateral, one side of the first island portion and one side of the second island portion face each other, and one side of the third island portion and one side of the fourth island portion face each other,
wherein two sides of the first island portion and the second island portion facing each other and two sides of the third island portion and the fourth island portion facing each other overlap four sides of a second imaginary quadrilateral, respectively, and
wherein one of the bridge portions are disposed within the second imaginary quadrilateral.

12. The display panel of claim 11, wherein the second imaginary quadrilateral is a square.

13. The display panel of claim 1, wherein each of the island portions includes a transistor and a light-emitting element electrically connected to the transistor, and each of the bridge portions includes wirings electrically connected to a transistor of at least one island portion among the island portions.

14. The display panel of claim 1, wherein the display panel is stretchable, and when the display panel is stretched, the island portions rotate clockwise or counterclockwise around an axis passing through the center of each of the island portions.

15. An electronic apparatus comprising:
a display panel providing images; and
a housing accommodating the display panel,
wherein the display panel includes:
island portions disposed in a display area and apart from each other in a first direction and a second direction perpendicular to the first direction; and
bridge portions connecting two island portions adjacent to each other among the island portions, the bridge portions being apart from each other by openings,
wherein the island portions have a quadrangular shape,
wherein each of the island portions includes a first side crossing an imaginary straight line extending in the first direction, the imaginary straight line passing through centers of the island portions, and
wherein an inferior angle of angles formed by the first side and the imaginary straight line is greater than 45° and less than 90°.

16. The electronic apparatus of claim 15, further comprising a strain sensor measuring a physical quantity according to stretching of the display panel.

17. The electronic apparatus of claim 15, wherein one of the bridge portions is disposed within a first imaginary quadrilateral having centers of four island portions adjacent to the bridge portion as vertexes.

18. The electronic apparatus of claim 15, wherein the island portions include first island portions and second island portions alternately disposed in the first direction and the second direction, and each of the bridge portions connects a first island portion and a second island portion adjacent to each other among the island portions.

19. The electronic apparatus of claim 18, wherein one end of each of the bridge portions is connected to a corner of one side of the first island portion, and
another end of each of the bridge portions is connected to a portion apart from a corner of one side of the second island portion.

20. The electronic apparatus of claim 18, wherein one side of the first island portion and one side of the second island portion connected to one of the bridge portions are disposed in directions crossing each other.
